(19) United States
(12) Patent Application Publication
(10) Pub. No.: US 2014/0069488 A1
(43) Pub. Date: Mar. 13, 2014

(54) CONDUCTIVE MEMBER, METHOD OF PRODUCING THE SAME, TOUCH PANEL, AND SOLAR CELL

(71) Applicant: FUJIFILM CORPORATION, TOKYO (JP)

(72) Inventors: Satoshi TANAKA, Ashigarakami-gun (JP); Shinichi NAKAHIRA, Ashigarakami-gun (JP); Yuki MATSUNAMI, Ashigarakami-gun (JP); Tomohito ASAI, Ashigarakami-gun (JP)

(73) Assignee: FUJIFILM CORPORATION, TOKYO (JP)

(21) Appl. No.: 14/062,504

(22) Filed: Oct. 24, 2013

Related U.S. Application Data
(63) Continuation of application No. PCT/JP2012/061464, filed on Apr. 27, 2012.

(30) Foreign Application Priority Data
Apr. 28, 2011 (JP) 2011-102135
Jan. 31, 2012 (JP) 2012-019250
Mar. 23, 2012 (JP) 2012-068239

(51) Int. Cl. H01B 1/22; H01L 21/02; H05K 1/02

(52) U.S. Cl. CPC H01B 1/22; H05K 1/02; H01L 21/02
USPC 136/252; 174/256; 349/12; 427/74; 252/514

(57) ABSTRACT

A conductive member including: a base material; and a conductive layer disposed on the base material, wherein the conductive layer includes: a metal nanowire including a metal element (a) and having an average minor axis length of 150 nm or less; and a sol-gel cured product obtained by hydrolyzing and polycondensing an alkoxide compound of an element (b) selected from the group consisting of Si, Ti, Zr, and Al; and a ratio of the substance amount of the element (b) contained in the conductive layer to the substance amount of the metal element (a) contained in the conductive layer is in a range of from 0.10/1 to 22/1.

### CROSS-REFERENCE TO RELATED APPLICATIONS

This application is a continuation application of International Application No. PCT/2012/061464, filed Apr. 27, 2012, which is incorporated herein by reference. Further, this application claims priority from Japanese Patent Application No. 2011-102135, filed Apr. 28, 2011, priority from Japanese Patent Application No. 2012-019250, filed Jan. 31, 2012, and priority from Japanese Patent Application No. 2012-068239, filed Mar. 23, 2012, which are incorporated herein by reference.

### TECHNICAL FIELD

The present invention relates to a conductive member, a production method therefor, a touch panel, and a solar cell.

### BACKGROUND ART

A conductive member having a conductive layer including a conductive fiber such as a metal nanowire has been proposed in recent years (e.g. see Japanese National Phase Publication (JP-A) No. 2009-505358). The conductive member has a conductive layer including plural metal nanowires on a base material. For example, when a photo-curable composition as a matrix is contained in the conductive layer, the conductive member can be easily processed into a conductive member having a conductive layer including desired conductive and non-conductive regions by pattern exposure and subsequent development. The processed conductive member can be applied to use, for example, in a touch panel or in an electrode for a solar cell.

It is also described that the conductive layer of the conductive member is made by dispersing or embedding the conductive member in a matrix material to improve physical and mechanical properties. In addition, an inorganic material such as a sol-gel matrix is exemplified as such a matrix material (e.g., see paragraphs 0045 to 0046 and 0051 of JP-A No. 2009-505358).

A conductive member in which a conductive layer containing, as a conductive layer having both of high transparency and high electrical conductivity, a transparent resin and a fiber-shaped conductive material such as a metal nanowire is disposed on a base material has been proposed. A resin obtained by thermally polymerizing a compound such as alkoxysilane or alkoxytitanium by a sol-gel method is exemplified as the transparent resin (e.g., see Japanese Patent Application Laid-Open (JP-A) No. 2010-121040 and Japanese Patent Application Laid-Open (JP-A) No. 2011-29098).

### SUMMARY OF INVENTION

The conductive members have been still susceptible to improvement in the film strength and wearing resistance of the conductive layers since the surfaces of the conductive layers are damaged or worn by repeating an operation of a touch panel, such as rubbing of the surfaces of the conductive layers with a tool with a sharp tip such as a pencil or a tool for operating a touch panel.

At least one of electrical conductivity and transparency may be deteriorated by exposing the conductive members to a high-temperature atmosphere or a high-temperature and high-humidity atmosphere for long time.

The above-described conductive members are susceptible to improvement in flexing resistance since, in a case in which the conductive members are used in touch panels with flexibility, the touch panels may undergo repeated bending operation for a long term and cracking or the like of the conductive layers may thus occur to deteriorate electrical conductivity.

A conductive member which has a conductive layer including a metal nanowire and which has high electrical conductivity, high transparency, and high film strength and is excellent in wearing resistance, heat resistance, resistance to moist heat, and flexing resistance has been demanded.

An object to be addressed by the present invention is to provide: a conductive member that has high electrical conductivity and high transparency and is excellent in wearing resistance, heat resistance, resistance to moist heat, and flexing resistance; a production method thereof; and a touch panel and a solar cell prepared by using the conductive member.

The present invention for solving the problem is as follows:

<1> A conductive member comprising a base material and a conductive layer disposed on the base material, wherein:

the conductive layer comprises:
a metal nanowire that comprises a metal element (a) and has an average minor axis length of 150 nm or less; and
a sol-gel cured product obtained by hydrolyzing and polycondensing an alkoxide compound of an element (b) selected from the group consisting of Si, Ti, Zr, and Al; and

a ratio of a substance amount of the element (b) contained in the conductive layer to a substance amount of the metal element (a) contained in the conductive layer is in a range of from 0.10/1 to 22/1.

<2> A conductive member comprising a base material and a conductive layer disposed on the base material, wherein:

the conductive layer comprises:
a metal nanowire that comprises a metal element (a) and has an average minor axis length of 150 nm or less; and
a sol-gel cured product comprising a three-dimensional crosslinked structure comprising at least one selected from the group consisting of a partial structure represented by the following Formula (1), a partial structure represented by the following Formula (2), and a partial structure represented by Formula (3); and

a ratio of a substance amount of the element (b) contained in the conductive layer to a substance amount of the metal element (a) contained in the conductive layer is in a range of from 0.10/1 to 22/1:

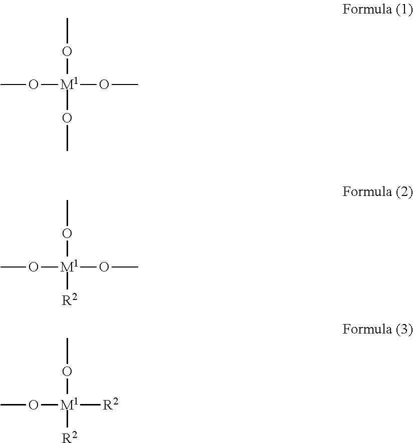

wherein M¹ represents an element selected from the group consisting of Si, Ti, and Zr; and each R² independently represents a hydrogen atom or a hydrocarbon group.

<3> A conductive member, comprising a base material and a conductive layer disposed on the base material, wherein:

the conductive layer comprises:
a metal nanowire that comprises a metal element (a) and has an average minor axis length of 150 nm or less; and
a sol-gel cured product obtained by hydrolyzing and polycondensing an alkoxide compound of an element (b) selected from the group consisting of Si, Ti, Zr, and Al; and

a ratio of the mass of the alkoxide compound hydrolyzed and polycondensed to form the sol-gel cured product in the conductive layer to the mass of the metal nanowire contained in the conductive layer is in a range of from 0.25/1 to 30/1.

<4> The conductive member according to <3>, wherein

the sol-gel cured product comprises a three-dimensional crosslinked structure comprising at least one selected from the group consisting of a partial structure represented by the following Formula (1), a partial structure represented by the following Formula (2), and a partial structure represented by Formula (3):

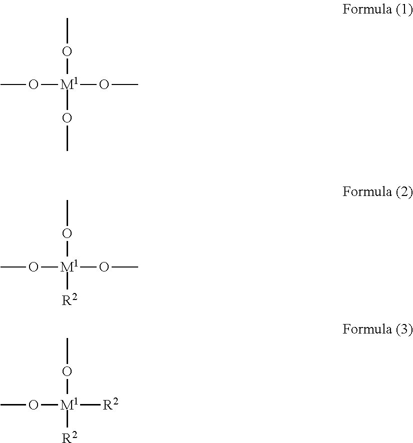

wherein M¹ represents an element selected from the group consisting of Si, Ti, and Zr; and each R² independently represents a hydrogen atom or a hydrocarbon group.

<5> The conductive member according to <1> or <3>, wherein the alkoxide compound comprises a compound represented by the following Formula (I):

M¹(OR¹)ₐR²₄₋ₐ (I)

wherein M¹ represents an element selected from the group consisting of Si, Ti, and Zr; R¹ and each R² independently represent a hydrogen atom or a hydrocarbon group; and a represents an integer from 2 to 4.

<6> The conductive member according to <2>, <4>, or <5>, wherein M¹ is Si.
<7> The conductive member according to any one of <1> to <6>, wherein the metal nanowire is a silver nanowire.
<8> The conductive member according to any one of <1> to <7>, wherein a surface resistivity of the conductive layer measured from a surface thereof is no more than 1,000 Ω/sq.
<9> The conductive member according to any one of <1> to <8>, wherein the conductive layer has an average film thickness of 0.005 μm to 0.5 μm.
<10> The conductive member according to any one of <1> to <9>, wherein the conductive layer comprises a conductive region and a non-conductive region; and at least the conductive region comprises the metal nanowire.
<11> The conductive member according to any one of <1> to <10>, further comprising at least one intermediate layer disposed between the base material and the conductive layer.
<12> The conductive member according to any one of <1> to <11>, further comprising an intermediate layer which is disposed between the base material and the conductive layer, which contacts the conductive layer, and which comprises a compound containing a functional group capable of interacting with the metal nanowire.
<13> The conductive member according to <12>, wherein the functional group is selected from the group consisting of an amide group, an amino group, a mercapto group, a carboxylic acid group, a sulfonic acid group, a phosphate group, a phosphonic acid group, and salts of these groups.
<14> The conductive member according to any one of <1> to <13>, wherein, in a case in which an wearing resistance test is conducted in which gauze is pressed on a surface of the conductive layer at a pressure of 125 g/cm² to rub the surface to and fro with the gauze 50 times using a continuous loading scratching tester, a ratio of a surface resistivity (Ω/sq.) of the conductive layer after the wearing resistance test to a surface resistivity (Ω/sq.) of the conductive layer before the wearing resistance test is 100 or less.
<15> The conductive member according to any one of <1> to <14>, wherein

a ratio of a surface resistivity (Ω/sq.) of the conductive layer after being subjected to a bending test to a surface resistivity (Ω/sq.) of the conductive layer of the conductive member before subjected to the bending test is 5.0 or less, and

the bending test comprises subjecting the conductive member to a 20-time bending test using a cylindrical mandrel bending tester equipped with a cylindrical mandrel having a diameter of 10 mm.

<16> A method of producing the conductive member according to any one of <3> to <15>, comprising:

(a) coating the base material with a liquid composition comprising the metal nanowire and the alkoxide compound in which a ratio of the mass of the alkoxide compound to the mass of the metal nanowire is in a range of from 0.25/1 to 30/1, to form a liquid film of the liquid composition on the base material; and

(b) hydrolyzing and polycondensing the alkoxide compound in the liquid film to obtain the sol-gel cured product.

<17> The method of producing the conductive member according to <16>, further comprising forming at least one intermediate layer on a surface of the base material on which the liquid film is formed, prior to the (a).
<18> The method of producing the conductive member according to <16> or <17>, further comprising (c) forming a pattern-shaped non-conductive region on the conductive layer after the (b) so that the conductive layer comprises a non-conductive region and a conductive region.
<19> A touch panel, comprising the conductive member according to any one of <1> to <15>.
<20> A solar cell, comprising the conductive member according to any one of <1> to <15>.
<21> A metal nanowire-containing composition comprising: a metal nanowire having an average minor axis length of 150 nm or less; and at least one alkoxide compound of an element (b) selected from the group consisting of Si, Ti, Zr, and Al, wherein a ratio of the mass of the alkoxide compound to the mass of the metal nanowire is in a range of from 0.25/1 to 30/1.

### Advantageous Effects of Invention

In accordance with the present invention, there can be provided: a conductive member that has high electrical conductivity and high transparency and is excellent in wearing resistance, heat resistance, resistance to moist heat, and flexing resistance; a production method thereof; and a touch panel and a solar cell prepared by using the conductive member.

### BRIEF DESCRIPTION OF DRAWINGS

FIG. 1 is a schematic cross-sectional view that illustrates a first exemplary embodiment of a conductive member according to a first embodiment of the present invention.

FIG. 2 is a schematic cross-sectional view that illustrates a second exemplary embodiment of the conductive member according to the first embodiment of the present invention.

### DESCRIPTION OF EMBODIMENTS

The conductive member of the present invention is explained in detail below.

The scope of the term “step” as used herein encompasses not only an independent step but also a step, in which the anticipated effect of this step is achieved, even if the step is not able to be definitely distinguished from another step.

The expression of a numerical value range (“from m to n” or “m to n”) refers to a range including, as the minimum value, a numerical value (m) represented as the lower limit of the numerical value range and including, as the maximum value, a numerical value (n) represented as the upper limit of the numerical value range.

For mentioning an amount of a certain constituent in a composition, in a case in which plural substances corresponding to the constituent are present in the composition, the amount means the total amount of the plural substances present in the composition unless otherwise specified.

As used herein, the term “light” is used as concepts including not only visible light rays but also high energy rays such as ultraviolet rays, X-rays, and gamma rays; corpuscular rays such as electron rays; and the like.

As used herein, the expressions “(meth)acrylic acid” may be used for representing any one or both of acrylic acid and methacrylic acid, and “(meth)acrylate” may be used for representing any one or both of acrylate and methacrylate.

A content is represented on a mass basis unless otherwise specified, mass % represents a percentage based on the total amount of a composition unless otherwise specified, and “solid content” represents a content of a constituent of a composition obtained by excluding a solvent in the composition.

Conductive Member

The conductive member according to one embodiment of the present invention includes at least a base material and a conductive layer disposed on the base material. The conductive layer includes at least: a metal nanowire including a metal element (a) and having an average minor axis length of 150 nm or less; and a sol-gel cured product obtained by hydrolyzing and polycondensing an alkoxide compound of an element (b) selected from the group consisting of Si, Ti, Zr, and Al. The conductive layer satisfies at least one of the following condition (i) or (ii).

(i) A ratio of a substance amount of the element (b) contained in the conductive layer to a substance amount of the metal element (a) contained in the conductive layer [(molar number of the element (b))/(molar number of the metal element (a))] is in a range of from 0.10/1 to 22/1.

(ii) A ratio of a mass of the alkoxide compound used to form the sol-gel cured product in the conductive layer to a mass of the metal nanowire contained in the conductive layer [(content of alkoxide compound)/(content of metal nanowire)] is in a range of from 0.25/1 to 30/1.

The conductive layer can be formed so that a ratio of the amount of a specific alkoxide compound used to the amount of the metal nanowire used, i.e., a ratio of [(mass of specific alkoxide compound)/(mass of metal nanowire)] is in a range of from 0.25/1 to 30/1. The mass ratio of 0.25/1 or more can result in the conductive layer excellent in transparency and excellent in all of wearing resistance, heat resistance, resistance to moist heat, and flexing resistance. The a mass ratio of 30/1 or less can result in the conductive layer excellent in electrical conductivity and flexing resistance.

The above-described mass ratio more preferably is in a range of 0.5/1 to 25/1, further preferably 1/1 to 20/1, most preferably is in a range of 2/1 to 15/1. The mass ratio in the preferable range results in the obtained conductive layer, which has high electrical conductivity and high transparency (total light transmittance and haze) and is excellent wearing resistance, heat resistance, resistance to moist heat, and flexing resistance, so that the conductive member having preferable physical properties can be stably obtained.

Examples of most preferable embodiments include an embodiment in which a ratio of the substance amount of the element (b) to the substance amount of the metal element (a) [(molar number of the element (b))/(molar number of the metal element (a))] in the conductive layer is in a range of from 0.10/1 to 22/1. The mole ratio ranges more preferably from 0.20/1 to 18/1, further preferably from 0.45/1 to 15/1, most preferably from 0.90/1 to 11/1.

The mole ratio in the above-described range can result in the conductive layer, which has both transparency and electrical conductivity and is excellent in wearing resistance, heat resistance, and resistance to moist heat as well as in flexing resistance from the viewpoint of physical properties.

Although the specific alkoxide compound used in the formation of the conductive layer is consumed by the hydrolysis and the polycondensation and the alkoxide compound does not substantially exist in the conductive layer, the obtained conductive layer contains the element (b) such as Si originating from the specific alkoxide compound. The conductive layer having excellent characteristics is formed by adjusting the ratio of the substance amount of the contained element (b) such as Si to the substance amount of the metal element (a) originating from the metal nanowire in the above-described range.

The element (b) selected from the group consisting of Si, Ti, Zr, and Al originating from a specific tetraalkoxide compound and the metal element (a) originating from a metal nanowire, which are constituents in the conductive layer, can be analyzed by a method below.

That is, a value of the substance amount ratio, i.e., (molar number of constituent of element (b))/(molar number of constituent of metal element (a)) can be calculated by subjecting the conductive layer to X-ray photoelectron analysis (Electron Spectroscopy for Chemical Analysis (ESCA)). However, the obtained value does not always directly indicate the mole ratio of the elemental constituents since the sensitivity of measurement in the analytical method by ESCA depends on each element. Therefore, a calibration curve is previously made using a conductive layer, of which the mole ratio of the elemental constituents is known, and the substance amount ratio of the actual conductive layer can be calculated from the calibration curve. The value calculated by the above-described method is used for the mole ratio of the respective elements as used herein.

The conductive member exhibits high electrical conductivity and high transparency as well as being excellent in wearing resistance, heat resistance, resistance to moist heat and flexing resistance. The reason thereof is not always clear but is presumed to be as follows.

That is, the conductive layer includes the metal nanowire and a matrix which is the sol-gel cured product obtained by hydrolyzing and polycondensing the specific alkoxide compound. Therefore, the conductive layer obtained can be closely packed and have a few gaps and a high crosslink density is formed even when the rate of the matrix contained in the conductive layer is in a low range compared with the case of a conductive layer including a common organic polymer resin (e.g., acrylic resin, vinyl polymer resin, or the like) as a matrix. Therefore, the conductive layer obtained can be excellent in wearing resistance, heat resistance, and resistance to moist heat is therefore obtained. Further, although a polymer having a hydrophilic group as a dispersing agent used during preparing metal nanowires represented by silver nanowires is presumed to interfere with contact of the metal nanowires at least to a certain extent, in the conductive component according to the present invention, the dispersing agent covering the metal nanowires is removed in the process of forming the sol-gel cured product, a polymer layer present in the state of coating a metal nanowire surface is further shrunk as a result of polycondensing of the specific alkoxide compound, and the contact points of the metal nanowires that are present in their vicinity and abundantly bought into contact with each other are therefore increased. It is considered that these actions cause the contact points of the metal nanowires that are present in their vicinity to be increased to result in high electrical conductivity and the small amount of the matrix needed for forming a layer results in high transparency. In addition, the effect of enhancing the above-described actions in a good balance and providing excellent wearing resistance, heat resistance, and resistance to moist heat as well as excellent flexing resistance while maintaining electrical conductivity and transparency is presumed to be caused by satisfying any of: the range of the content mole ratio of the element (b) originating from the specific alkoxide compound/the metal element (a) originating from the metal nanowire of 0.10/1 to 22/1; and the range of the mass ratio of the alkoxide compound/the metal nanowire of 0.25/1 to 30/1 related thereto.

Each component constituting the conductive member of the present invention is explained in detail below.

Base Material

Various base materials can be used for the base material depending on a purpose as long as the conductive layer can be disposed thereon. In general, a plate-shaped or sheet-shaped base material is used.

The base material may be transparent or opaque. Examples of materials of the base material include transparent glass such as clear glass, soda lime glass, or silica-coated soda lime glass; synthetic resins such as polycarbonate, polyether sulfone, polyester, acryl resins, vinyl chloride resins, aromatic polyamide resins, polyamide-imide, and polyimide; metals such as aluminum, copper, nickel, and stainless steel; ceramic, a silicon wafer used in a semiconductor substrate, and the like. The surfaces, on which the conductive layer is to be formed, of these base material may also be subjected to pretreatment by cleaning treatment with an aqueous alkaline solution, chemical treatment with a silane coupling agent or the like, plasma treatment, ion plating, sputtering, vapor phase reaction, vacuum deposition, or the like, as desired.

The base material having a thickness in a desired range depending on use is used. The thickness is generally selected from the range of 1 μm to 500 μm, more preferably 3 μm to 400 μm, further preferably 5 μm to 300 μm.

In a case in which the conductive member requires transparency, the base material preferably has a total visible light transmittance of 70% or more, more preferably 85% or more, further preferably 90% or more. The light transmittance of the base material is measured according to ISO 13468-1 (1996).

Conductive Layer

The conductive layer includes a metal nanowire having an average minor axis length of 150 nm or less and a matrix which is a sol-gel cured product obtained by hydrolyzing and polycondensing at least one alkoxide compound of an element (b) selected from the group consisting of Si, Ti, Zr, and Al. The conductive layer satisfies at least any one of conditions that (i) a ratio of a substance amount of an element (b) selected from the group consisting of Si, Ti, Zr, and Al originating from the alkoxide compound to a substance amount of a metal element (a) originating from the metal nanowire [(molar number of contained element (b))/(molar number of contained metal element (a))] is in a range of from 0.10/1 to 22/1; and (ii) a mass ratio of the alkoxide compound to the metal nanowire [(content of alkoxide compound)/(content of metal nanowire)] is in a range of from 0.25/1 to 30/1.

Metal Nanowire Having Average Minor Axis Length of 150 nm or Less

The conductive layer includes a metal nanowire having an average minor axis length of 150 nm or less. The average minor axis length of more than 150 nm is not preferable since electrical conductivity may be deteriorated or optical characteristics may be deteriorated due to light scattering or the like. The metal nanowire preferably has a solid structure.

For example, the metal nanowire preferably has an average minor axis length of from 1 nm to 150 nm and an average major axis length of from 1 μm to 100 μm from the viewpoint of facilitating the formation of a more transparent conductive layer.

In view of easiness in handling during production, the average minor axis length (average diameter) of the metal nanowire is preferably 100 nm or less, more preferably 60 nm or less, and further preferably 50 nm or less. It is particularly preferably 25 nm or less in view of obtaining superior haze. The average minor axis length of 1 nm or more allows a conductive member having good oxidation resistance and excellent weathering resistance to be easily obtained. The average minor axis length is more preferably 5 nm or more, further preferably 10 nm or more, particularly preferably 15 nm or more.

The average minor axis length of the metal nanowire is preferably 1 nm to 100 nm, more preferably 5 nm to 60 nm, further preferably 10 nm to 60 nm, particularly preferably 15 nm to 50 nm, from the viewpoint of a haze value, oxidation resistance, and weathering resistance.

The average major axis length of the metal nanowire is preferably 1 μm to 40 μm, more preferably 3 μm to 35 μm, further preferably 5 μm to 30 μm. The average major axis length of the metal nanowire of 40 μm or less facilitates easily synthesizing of the metal nanowire without generating an agglomerate while the average major axis length of 1 μm or more facilitates easily obtaining sufficient electrical conductivity. The average minor axis length (average diameter) and average major axis length of the metal nanowire can be determined by, for example, observing a transmission electron microscope (TEM) image or an optical microscope image using a TEM or and an optical microscope. Specifically, as for the average minor axis length (average diameter) and average major axis length of the metal nanowire, the average minor axis length and average major axis length of the metal nanowire can be determined from the average values of the minor axis lengths and major axis lengths of randomly selected 300 metal nanowires, measured using a transmission electron microscope (trade name: JEM-2000FX, manufactured by JEOL Ltd.). The values determined by this method are adopted herein. As for a minor axis length in a case in which the cross section in the minor axis direction of the metal nanowire is not circular, the length of the longest portion measured in the minor axis direction is regarded as the minor axis length. In a case in which the metal nanowire bends, a circle which has the metal nanowire as an are thereof is considered, and a value calculated based on the radius and curvature of the circle is regarded as a major axis length.

In one embodiment, the content of metal nanowires having a minor axis length (diameter) of 150 nm or less and a major axis length of from 5 μm to 500 μm based on the content of all the metal nanowires in the conductive layer is, in terms of a metal content, preferably 50 mass % or more, more preferably 60 mass % or more, and further preferably 75 mass % or more.

The content of the metal nanowires having the minor axis length (diameter) of 150 nm or less and the length of from 5 μm to 500 μm of 50 mass % or more is preferable since sufficient conductivity can be obtained and voltage concentration can be precluded to be able to suppress deterioration of durability caused by voltage concentration. In a structure in which conductive particles that are not fibrous are not substantially contained in the conductive layer, deterioration of transparency can be avoided even in a case of high plasmon absorption.

The coefficient of variation of the minor axis length (diameter) of the metal nanowire used in the conductive layer is preferably 40% or less, more preferably 35% or less, further preferably 30% or less.

The coefficient of variation of 40% or less may suppress deterioration in durability. This can be considered to be because, for example, the concentration of a voltage on a wire having a small minor axis length (diameter) can be avoided.

The coefficient of variation of the minor axis length (diameter) of the metal nanowire can be determined by, for example, measuring the minor axis lengths (diameters) of 300 nanowires randomly selected from a transmission electron microscope (TEM) image, calculating the standard deviation and arithmetic mean value thereof, and dividing the standard deviation by the arithmetic mean value.

(Aspect Ratio of Metal Nanowire)

The aspect ratio of the metal nanowire that can be used in the present invention is preferably 10 or more. As used herein, the aspect ratio means a ratio of an average major axis length to an average minor axis length (average major axis length/average minor axis length). The aspect ratio can be calculated from the average major axis length and the average minor axis length calculated by the above-mentioned method.

The aspect ratio of the metal nanowire is not particularly limited as long as the aspect ratio is 10 or more, and can be appropriately selected depending on a purpose. It is preferably from 10 to 100,000, further preferably from 50 to 100,000, more preferably from 100 to 100,000.

When the aspect ratio is 10 or more, a network in which metal nanowires are brought into contact with each other is easily formed to easily provide a conductive layer having high electrical conductivity. Further, when the aspect ratio is 100,000 or less, for example, as for a coating liquid for disposing the conductive layer on the base material by coating, the metal nanowires may be inhibited from being entangled with each other to form an agglomerate, the coating liquid may be obtained as a stable one, and the conductive member may be therefore easily produced.

The content of the metal nanowire having an aspect ratio of 10 or more based on the mass of all the metal nanowires contained in the conductive layer is not particularly limited. For example, the content is preferably 70 mass % or more, more preferably 75 mass % or more, and most preferably 80% mass % or more.

The shape of the metal nanowire may be an arbitrary shape such as a cylindrical shape, a rectangular parallelepiped shape, or a column shape with a polygonal cross section, and is preferably a cylindrical shape or a cross-sectional shape with a cross section having a polygonal shape that is pentagonal or more polygonal and without any acute-angle corner for uses in which high transparency is required.

The cross-sectional shape of the metal nanowire can be detected by coating the base material with an aqueous dispersion of the metal nanowire and observing the cross section with a transmission electron microscope (TEM).

A metal for forming the metal nanowire is not particularly limited and may be any metal. In addition to one metal, two or more metals may be used in combination or an alloy can also be used. Of these, a metal nanowire formed of a single metal or a metal compound is preferable, and a metal nanowire formed of a single metal is more preferable.

The metal is preferably at least one metal selected from the group consisting of the fourth, fifth, and sixth periods in the long periodic table (IUPAC1991), more preferably at least one metal selected from Groups 2 to 14, further preferably at least one metal selected from Group 2, Group 8, Group 9, Group 10, Group 11, Group 12, Group 13, and Group 14, and particularly preferably includes these metals as the main components.

Specific examples of the metals include copper, silver, gold, platinum, palladium, nickel, tin, cobalt, rhodium, iridium, iron, ruthenium, osmium, manganese, molybdenum, tungsten, niobium, tantalum, titanium, bismuth, antimony, lead, an alloy containing any of these, and the like. Of these, copper, silver, gold, platinum, palladium, nickel, tin, cobalt, rhodium, iridium, and an alloy thereof are preferable, palladium, copper, silver, gold, platinum, tin, and an alloy containing any of these are more preferable, and silver and an alloy containing silver are particularly preferable. The content of silver in the alloy containing the silver is preferably 50 mol % or more, more preferably 60 mol % or more, further preferably 80 mol % or more, based on the total amount of the alloy.

The metal nanowire contained in the conductive layer preferably includes a silver nanowire, more preferably a silver nanowire having an average minor axis length of 1 nm to 150 nm and an average major axis length of 1 μm to 100 μm, further preferably a silver nanowire having an average minor axis length of 5 nm to 30 nm and an average major axis length of 5 μm to 30 μm, from the viewpoint of realizing high electrical conductivity. The content of silver nanowires based on the mass of all the metal nanowires contained in the conductive layer is not particularly limited unless interfering with the effects of the present invention. For example, the content of the silver nanowire based on the mass of all the metal nanowires contained in the conductive layer is preferably 50 mass % or more, more preferably 80 mass % or more, and it is further preferable that all the metal nanowires are substantially silver nanowires. As used herein, “substantially” means that unavoidable incorporation of any metal atom other than silver is permitted.

The content of the metal nanowire contained in the conductive layer is preferably such an amount that the surface resistivity, total light transmittance, and haze value of the conductive member is in a desired range depending on, e.g., the kind of the metal nanowire. For example, in the case of silver nanowire, the content (content (g) of metal nanowires per cubic meter of conductive layer) is in a range of from 0.001 g/m² to 0.100 g/m², preferably in a range of from 0.002 g/m² to 0.050 g/m², and more preferably in a range of from 0.003 g/m² to 0.040 g/m²

The conductive layer preferably includes a metal nanowire having an average minor axis length of 5 nm to 60 nm in a range of from 0.001 g/m² to 0.100 g/m², more preferably includes a metal nanowire having an average minor axis length of 10 nm to 60 nm in a range of from 0.002 g/m² to 0.050 g/m², and further preferably includes a metal nanowire having an average minor axis length of 20 nm to 50 nm in a range of from 0.003 g/m² to 0.040 g/m² from the viewpoint of electrical conductivity.

(Method of Producing Metal Nanowire)

The metal nanowire may be produced by any method without particular limitation. The metal nanowire is preferably produced by reducing metal ions in a solvent in which a halogen compound and a dispersing agent are dissolved, as described below. Further, it is preferable that the metal nanowire is formed and then subjected to desalting treatment by a usual method, from the viewpoint of dispersibility and the temporal stability of a conductive layer.

As the method of producing the metal nanowire, methods described in Japanese Patent Application Laid-Open (JP-A) No. 2009-215594, Japanese Patent Application Laid-Open (JP-A) No. 2009-242880, Japanese Patent Application Laid-Open (JP-A) No. 2009-299162, Japanese Patent Application Laid-Open (JP-A) No. 2010-84173, Japanese Patent Application Laid-Open (JP-A) No. 2010-86714, and the like can be used.

The solvent used for producing the metal nanowire is preferably a hydrophilic solvent, examples thereof include water, alcohol solvents, ether solvents, ketone solvents, and the like, and they may be used alone or in combination of two or more.

Examples of the alcohol solvents include methanol, ethanol, propanol, isopropanol, butanol, ethylene glycol, and the like.

Examples of the ether solvents include dioxane, tetrahydrofuran, and the like.

Examples of the ketone solvents include acetone and the like.

In the case of heating, heating temperature in the case is preferably 250° C. or less, more preferably from 20° C. to 200° C., further preferably from 30° C. to 180° C., and particularly preferably 40° C. to 170° C. Since the above-described temperature of 20° C. or more causes the lengths of formed metal nanowires to be in a preferable range in which dispersion stability can be secured and the above-described temperature of 250° C. or less causes the perimeters of the cross sections of the metal nanowires to have smooth shapes without any acute angles, the above-described temperature is preferable from the viewpoint of transparency.

In addition, temperature may be optionally changed in the process of forming particles and the change of the temperature during the process may have the effect of improvement in monodispersibility due to controlling of nucleus formation, suppression of renucleation, and acceleration of selective growth.

It is preferable to carry out the heat treatment with addition of a reducing agent.

The reducing agent is not particularly limited and can be appropriately selected from usually used reducing agents, and examples thereof include boron hydride metal salts, aluminum hydride salts, alkanolamine, aliphatic amines, heterocyclic amines, aromatic amines, aralkyl amines, alcohols, organic acids, reducing sugars, sugar alcohols, sodium sulfite, hydrazine compounds, dextrin, hydroquinone, hydroxylamine, ethylene glycol, glutathione, and the like. Of these, reducing sugars, sugar alcohols as the derivatives thereof, and ethylene glycol are particularly preferable.

In the reducing agents, there are compounds that function as a dispersing agent or a solvent as a function and the compounds can be similarly preferably used.

It is preferable to carry out the production of the metal nanowire with adding a dispersing agent and a halogen compound or fine metal halide particles.

The timing of the addition of the dispersing agent and the halogen compound may be before or after the addition of the reducing agent and may be before or after the addition of metal ions or the fine metal halide particles, and it is preferable to divide the addition of the halogen compound into two or more stages in order to obtain the nanowire with better monodispersibility probably because nucleus formation and growth can be controlled.

The stage of the addition of the dispersing agent is not particularly limited. The addition may be carried out before preparing metal nanowires to add the metal nanowires under the presence of the dispersing agent or the addition may be carried out for regulating a dispersion state after preparing metal nanowires.

Examples of the dispersing agent include amino group-containing compounds, thiol group-containing compounds, sulfide group-containing compounds, amino acids or derivatives thereof, peptide compounds, polysaccharides, natural polymers originating from polysaccharides, synthetic polymers, high-molecular compounds such as gels originating therefrom, or the like. Of these, various high-molecular compounds used as dispersing agents are compounds encompassed by polymers described below.

Preferable examples of the polymers that are preferably used as the dispersing agents include polymers having hydrophilic groups, such as gelatin which is a polymer with protective colloid properties, polyvinyl alcohols, methylcellulose, hydroxypropylcellulose, polyalkylene amines, partial alkyl esters of polyacrylic acids, polyvinylpyrrolidone, copolymers containing polyvinylpyrrolidone structures, and polyacrylic acids having amino groups or thiol groups.

The polymer used as the dispersing agent has a weight average molecular weight (Mw), measured by gel permeation chromatography (GPC), of from 3000 to 300000, which is more preferably from 5000 to 100000.

As for the structure of a compound which can be used as the dispersing agent, for example, the description of “Dictionary of Pigments” Seishiro Ito ed (2000, published by Asakura Publishing Co., Ltd.) can be seen.

The shape of a resultant metal nanowire can be changed depending on the kind of the dispersing agent used.

The halogen compound is not particularly limited, as long as the halogen compound is a compound containing bromine, chlorine, or iodine, and can be appropriately selected depending on a purpose, and is preferably, for example, an alkali halide, such as sodium bromide, sodium chloride, sodium iodide, potassium iodide, potassium bromide, potassium chloride, or potassium iodide, or a compound that can be used together with a dispersion additive described below.

As the halogen compound, there can be a halogen compound that functions as a dispersion additive, and the halogen compound can be similarly preferably used.

As a substitute for the halogen compound, fine silver halide particles may be used or a halogen compound and fine silver halide particles may be used together.

A single substance having both functions of a dispersing agent and a halogen compound may also be used. In other words, both functions of the dispersing agent and the halogen compound are expressed in one compound by using the halogen compound having the function of the dispersing agent.

Examples of the halogen compound having the function of the dispersing agent include: hexadecyl-trimethylammonium bromide (HTAB) containing an amino group and bromide ions; hexadecyl-trimethylammonium chloride (HTAC) containing an amino group and chloride ions; dodecyltrimethylammonium bromide, dodecyltrimethylammonium chloride, stearyltrimethylammonium bromide, stearyltrimethylammonium chloride, decyltrimethylammonium bromide, decyltrimethylammonium chloride, dimethyldistearylammonium bromide, dimethyldistearylammonium chloride, dilauryldimethylammonium bromide, dilauryldimethylammonium chloride, dimethyldipalmitylammonium bromide, and dimethyldipalmitylammonium chloride, containing an amino group and bromide or chloride ions; and the like.

In the method of producing the metal nanowire, it is preferable that the metal nanowire is formed and then subjected to desalting treatment. The desalting treatment after the formation of the metal nanowire can be carried out by a technique such as ultrafiltration, dialysis, gel filtration, decantation, or centrifugation.

The metal nanowire preferably excludes inorganic ions such as alkali metal ions, alkaline earth metal ions, and halide ions, if possible. The electric conductivity of a dispersion prepared by dispersing the metal nanowire in an aqueous solvent is preferably 1 mS/cm or less, more preferably 0.1 mS/cm or less, and further preferably 0.05 mS/cm or less.

The viscosity of the aqueous dispersion of the metal nanowire at 20° C. is preferably 0.5 mPa·s to 100 mPa·s, and more preferably 1 mPa·s to 50 mPa·s.

The electric conductivity and the viscosity are measured at a concentration of the metal nanowire in the aqueous dispersion of 0.45 mass %. In a case in which the concentration of the metal nanowire in the aqueous dispersion is higher than the above-described concentration, the measurement is carried out with diluting the aqueous dispersion with distilled water.

<Sol-Gel Cured Product>

A sol-gel cured product contained in the conductive layer is explained below.

The above-described sol-gel cured product is obtained by hydrolyzing and polycondensing an alkoxide compound (hereinafter also referred to as “specific alkoxide compound”) of an element (a) selected from the group consisting of Si, Ti, Zr, and Al. The specific alkoxide compound may be further optionally heated and dried, as desired, after prepared by the hydrolysis and the polycondensation.

### [Specific Alkoxide Compound]

In view of availability, the specific alkoxide compound is preferably a compound represented by the following Formula (I):

M¹(OR¹)ₐR²₄₋ₐ (I)

(in Formula (I), M¹ represents an element selected from the group consisting of Si, Ti, and Zr; R¹ and R² each independently represent a hydrogen atom or a hydrocarbon group; and a represents an integer from 2 to 4).

Preferable examples of each hydrocarbon group of R¹ and R² in Formula (I) include an alkyl group or an aryl group.

In the case of representing an alkyl group, the number of carbon atoms is preferably 1 to 18, more preferably 1 to 8, and further more preferably 1 to 4. In the case of representing an aryl group, a phenyl group is preferable.

The alkyl group or the aryl group may or may not have a substituent. Examples of the substituent that can be introduced include a halogen atom, an amino group, an alkylamino group, a mercapto group, and the like. It is preferable that the compound represented by Formula (I) is a low molecular weight compound and has a molecular weight of 1000 or less.

Specific examples of the compound represented by Formula (I) are mentioned below, but the present invention is not limited thereto.

In a case in which M¹ is Si and a is 2, i.e., examples of bifunctional organoalkoxy silanes, include dimethyl dimethoxy silane, diethyl dimethoxy silane, propyl methyl dimethoxy silane, dimethyl diethoxy silane, diethyl diethoxy silane, dipropyl diethoxy silane, γ-chloropropyl methyl diethoxy silane, γ-chloropropyl dimethyl dimethoxy silane, chlorodimethyl diethoxy silane, (p-chloromethyl)phenyl methyl dimethoxy silane, γ-bromopropyl methyl dimethoxy silane, acetoxymethyl methyl diethoxy silane, acetoxymethyl methyl dimethoxy silane, acetoxypropyl methyl dimethoxy silane, benzoyloxy propyl methyl dimethoxy silane, 2-(carbomethoxy)ethyl methyl dimethoxy silane, phenyl methyl dimethoxy silane, phenyl ethyl diethoxy silane, phenyl methyl dipropoxy silane, hydroxy methyl methyl diethoxy silane, N-(methyldiethoxysilylpropyl)-O-polyethylene oxide urethane, N-(3-methyldiethoxysilylpropyl)-4-hydroxybutyramide, N-(3-methyldiethoxysilylpropyl)gluconamide, vinyl methyl dimethoxy silane, vinyl methyl diethoxy silane, vinyl methyl dibutoxy silane, isopropenyl methyl dimethoxy silane, isopropenyl methyl diethoxy silane, isopropenyl methyl dibutoxy silane, vinyl methyl bis(2-methoxyethoxy)silane, allyl methyl dimethoxy silane, vinyl decyl methyl dimethoxy silane, vinyl octyl methyl dimethoxy silane, vinyl phenyl methyl dimethoxy silane, isopropenyl phenyl methyl dimethoxy silane, 2-(meth)acryloxy ethyl methyl dimethoxy silane, 2-(meth)acryloxy ethyl methyl diethoxy silane, 3-(meth)acryloxy propyl methyl dimethoxy silane, 3-(meth)acryloxy propyl methyl dimethoxy silane, 3-(meth)-acryloxy propyl methyl bis(2-methoxyethoxy)silane, 3-[2-(allyloxycarbonyl)phenylcarbonyloxy]propyl methyl dimethoxy silane, 3-(vinylphenylamino)propyl methyl dimethoxy silane, 3-(vinylphenylamino)propyl methyl diethoxy silane, 3-(vinylbenzylamino)propyl methyl diethoxy silane, 3-(vinylbenzylamino)propyl methyl diethoxy silane, 3-[2-(N-vinylphenylmethylamino)ethylamino]propyl methyl dimethoxy silane, 3-[2-(N-isopropenylphenylmethylamino)ethylamino]propyl methyl dimethoxy silane, 2-(vinyloxy)ethyl methyl dimethoxy silane, 3-(vinyloxy)propyl methyl dimethoxy silane, 4-(vinyloxy)butyl methyl diethoxy silane, 2-(isopropenyloxy)ethyl methyl dimethoxy silane, 3-(allyloxy)propyl methyl dimethoxy silane, 10-(allyloxycarbonyl)decyl methyl dimethoxy silane, 3-(isopropenylmethyloxy)propyl methyl dimethoxy silane, 10-(isopropenylmethyloxycarbonyl)decyl methyl dimethoxy silane, 3-[(meth)acryloxypropyl]methyl dimethoxy silane, 3-[(meth)acryloxypropyl]methyl diethoxy silane, 3-[(meth)acryloxymethyl]methyl dimethoxy silane, 3-[(meth)acryloxymethyl]methyl diethoxy silane, γ-glycidoxy propyl methyl dimethoxy silane, N-[3-(meth)acryloxy-2-hydroxypropyl]-3-aminopropyl methyl diethoxy silane, O-[(meth)acryloxyethyl]-N-(methyldiethoxysilylpropyl)urethane, γ-glycidoxy propyl methyl diethoxy silane, β-(3,4-epoxycyclohexyl)ethyl methyl dimethoxy silane, γ-aminopropyl methyl diethoxy silane, γ-aminopropyl methyl dimethoxy silane, 4-aminobutyl methyl diethoxy silane, 11-aminoundecyl methyl diethoxy silane, m-aminophenyl methyl dimethoxy silane, p-aminophenyl methyl dimethoxy silane,

3-aminopropyl methyl-bis(methoxyethoxy)silane, 2-(4-pyridylethyl)methyl diethoxy silane, 2-(methyldimethoxysilylethyl)pyridine, N-(3-methyldimethoxysilylpropyl)pyrrole, 3-(m-aminophenoxy)propyl methyl dimethoxy silane, N-(2-aminoethyl)-3-aminopropyl methyl dimethoxy silane, N-(2-aminoethyl)-3-aminopropyl methyl diethoxy silane, N-(6-aminohexyl)aminomethyl methyl diethoxy silane, N-(6-aminohexyl)aminopropyl methyl dimethoxy silane, N-(2-aminoethyl)-11-aminoundecyl methyl dimethoxy silane, (aminoethylaminomethyl)phenethyl methyl dimethoxy silane, N-3-[(amino(polypropyleneoxy))]aminopropyl methyl dimethoxy silane, n-butyl aminopropyl methyl dimethoxy silane, N-ethyl amino isobutyl methyl dimethoxy silane, N-methyl aminopropyl methyl dimethoxy silane, N-phenyl-γ-aminopropyl methyl dimethoxy silane, N-phenyl-γ-aminomethyl methyl diethoxy silane, (cyclohexylaminomethyl)methyl diethoxy silane, N-cyclohexyl aminopropyl methyl dimethoxy silane, bis(2-hydroxyethyl)-3-aminopropyl methyl diethoxy silane, diethyl aminomethyl methyl diethoxy silane, diethyl aminopropyl methyl dimethoxy silane, dimethyl aminopropyl methyl dimethoxy silane, N-3-methyldimethoxysilylpropyl-m-phenylenediamine, N,N-bis[3-(methyldimethoxysilyl)propyl]ethylenediamine, bis(methyldiethoxysilylpropyl)amine, bis(methyldimethoxysilylpropyl)amine, bis[(3-methyldimethoxysilyl)propyl]-ethylenediamine, bis[3-(methyldiethoxysilyl)propyl]urea, bis(methyldimethoxysilylpropyl)urea, N-(3-methyldiethoxysilylpropyl)-4,5-dihydroimidazol, ureidopropyl methyl diethoxy silane, ureidopropyl methyl dimethoxy silane, acetamidopropyl methyl dimethoxy silane, 2-(2-pyridylethyl)thiopropyl methyl dimethoxy silane, 2-(4-pyridylethyl)thiopropyl methyl dimethoxy silane, bis[3-(methyldiethoxysilyl)propyl]disulfide, 3-(methyldiethoxysilyl)propylsuccinic anhydride, γ-mercaptopropyl methyl dimethoxy silane, γ-mercaptopropyl methyl diethoxy silane, isocyanatopropyl methyl dimethoxy silane, isocyanatopropyl methyl diethoxy silane, isocyanatoethyl methyl diethoxy silane, isocyanatomethyl methyl diethoxy silane, carboxyethyl methyl silane diol sodium salt, N-(methyldimethoxysilylpropyl)ethylenediaminetriacetic acid trisodium salt, 3-(methyldihydroxysilyl)-1-propanesulfonic acid, diethyl phosphate ethyl methyl diethoxy silane, 3-methyl dihydroxy silyl propyl methyl phosphonate sodium salt, bis(methyldiethoxysilyl)ethane, bis(methyldimethoxysilyl)ethane, bis(methyldiethoxysilyl)methane, 1,6-bis(methyldiethoxysilyl)hexane, 1,8-bis(methyldiethoxysilyl)octane, p-bis(methyldimethoxysilylethyl)benzene, p-bis(methyldimethoxysilylmethyl)benzene, 3-methoxy propyl methyl dimethoxy silane, 2-[methoxy(polyethyleneoxy)propyl]methyl dimethoxy silane, methoxy triethyleneoxy propyl methyl dimethoxy silane, tris(3-methyldimethoxysilylpropyl)isocyanurate, [hydroxy(polyethyleneoxy)propyl]methyl diethoxy silane, N,N′-bis(hydroxyethyl)-N,N′-bis(methyldimethoxysilylpropyl)ethylenediamine, bis-[3-(methyldiethoxysilylpropyl)-2-hydroxypropoxy]polyethylene oxide, bis[N,N′-(methyldiethoxysilylpropyl)aminocarbonyl]polyethylene oxide, and bis(methyldiethoxysilylpropyl)polyethylene oxide. Of these, particularly preferable examples include dimethyl dimethoxy silane, diethyl dimethoxy silane, dimethyl diethoxy silane, diethyl diethoxy silane, and the like from the viewpoint of availability and the viewpoint of adhesiveness with a hydrophilic layer.

In a case in which M¹ is Si and a is 3, i.e., examples of trifunctional organoalkoxy silanes include methyl trimethoxy silane, ethyl trimethoxy silane, propyl trimethoxy silane, methyl triethoxy silane, ethyl triethoxy silane, propyl triethoxy silane, γ-chloropropyl triethoxy silane, γ-chloropropyl trimethoxy silane, chloromethyl triethoxy silane, (p-chloromethyl)phenyl trimethoxy silane, γ-bromopropyl trimethoxy silane, acetoxymethyl triethoxy silane, acetoxymethyl trimethoxy silane, acetoxypropyl trimethoxy silane, benzoyloxy propyl trimethoxy silane, 2-(carbomethoxy)ethyl trimethoxy silane, phenyl trimethoxy silane, phenyl triethoxy silane, phenyl tripropoxy silane, hydroxy methyl triethoxy silane, N-(triethoxysilylpropyl)-O-polyethylene oxide urethane, N-(3-triethoxysilylpropyl)-4-hydroxybutyramide, N-(3-triethoxysilylpropyl)gluconamide, vinyl trimethoxy silane, vinyl triethoxy silane, vinyl tributoxy silane, isopropenyl trimethoxy silane, isopropenyl triethoxy silane, isopropenyl tributoxy silane, vinyl tris(2-methoxyethoxy)silane, allyl trimethoxy silane, vinyl decyl trimethoxy silane, vinyl octyl trimethoxy silane, vinyl phenyl trimethoxy silane, isopropenyl phenyl trimethoxy silane, 2-(meth)acryloxy ethyl trimethoxy silane, 2-(meth)acryloxy ethyl triethoxy silane, 3-(meth)acryloxy propyl trimethoxy silane, 3-(meth)acryloxy propyl trimethoxy silane, 3-(meth)-acryloxy propyl tris(2-methoxyethoxy)silane, 3-[2-(allyloxycarbonyl)phenylcarbonyloxy]propyl trimethoxy silane, 3-(vinylphenylamino)propyl trimethoxy silane, 3-(vinylphenylamino)propyl triethoxy silane, 3-(vinylbenzylamino)propyl triethoxy silane, 3-(vinylbenzylamino)propyl triethoxy silane, 3-[2-(N-vinylphenylmethylamino)ethylamino]propyl trimethoxy silane, 3-[2-(N-isopropenylphenylmethylamino)ethylamino]propyl trimethoxy silane, 2-(vinyloxy)ethyl trimethoxy silane, 3-(vinyloxy)propyl trimethoxy silane, 4-(vinyloxy)butyl triethoxy silane, 2-(isopropenyloxy)ethyl trimethoxy silane, 3-(allyloxy)propyl trimethoxy silane, 10-(allyloxycarbonyl)decyl trimethoxy silane, 3-(isopropenylmethyloxy)propyl trimethoxy silane, 10-(isopropenylmethyloxycarbonyl)decyl trimethoxy silane, 3-[(meth)acryloxypropyl]trimethoxy silane, 3-[(meth)acryloxypropyl]triethoxy silane, 3-[(meth)acryloxymethyl]trimethoxy silane, 3-[(meth)acryloxymethyl]triethoxy silane, γ-glycidoxy propyl trimethoxy silane, N-[3-(meth)acryloxy-2-hydroxypropyl]-3-aminopropyl triethoxy silane, O-[(meth)acryloxyethyl]-N-(triethoxysilylpropyl)urethane, γ-glycidoxy propyl triethoxy silane, (3-(3,4-epoxycyclohexyl)ethyl trimethoxy silane, γ-aminopropyl triethoxy silane, γ-aminopropyl trimethoxy silane, 4-aminobutyl triethoxy silane, 11-aminoundecyl triethoxy silane, m-aminophenyl trimethoxy silane, p-aminophenyl trimethoxy silane, 3-aminopropyl tris(methoxyethoxyethoxy)silane,

2-(4-pyridylethyl)triethoxy silane, 2-(trimethoxysilylethyl)pyridine, N-(3-trimethoxysilylpropyl)pyrrole, 3-(m-aminophenoxy)propyl trimethoxy silane, N-(2-aminoethyl)-3-aminopropyl trimethoxy silane, N-(2-aminoethyl)-3-aminopropyl triethoxy silane, N-(6-aminohexyl)aminomethyl triethoxy silane, N-(6-aminohexyl)aminopropyl trimethoxy silane, N-(2-aminoethyl)-1-aminoundecyl trimethoxy silane, (aminoethylaminomethyl)phenethyl trimethoxy silane, N-3-[(amino(polypropyleneoxy))]aminopropyl trimethoxy silane, N-butyl aminopropyl trimethoxysilane, N-ethyl amino isobutyl trimethoxy silane, N-methyl aminopropyl trimethoxy silane, N-phenyl-γ-aminopropyl trimethoxy silane, N-phenyl-γ-aminomethyl triethoxy silane, (cyclohexylaminomethyl)triethoxy silane, N-cyclohexyl aminopropyl trimethoxy silane, bis(2-hydroxyethyl)-3-aminopropyl triethoxy silane, diethyl aminomethyl triethoxy silane, diethyl aminopropyl trimethoxy silane, dimethyl aminopropyl trimethoxy silane, N-3-trimethoxysilylpropyl-m-phenylenediamine, N,N-bis[3-(trimethoxysilyl)propyl]ethylenediamine, bis(triethoxysilylpropyl)amine, bis(trimethoxysilylpropyl)amine, bis[(3-trimethoxysilyl)propyl]-ethylenediamine, bis[3-(triethoxysilyl)propyl]urea, bis(trimethoxysilylpropyl)urea, N-(3-triethoxysilylpropyl)-4,5-dihydroimidazol, ureidopropyl triethoxy silane, ureidopropyl trimethoxy silane, acetamide propyl trimethoxy silane, 2-(2-pyridylethyl)thiopropyl trimethoxy silane, 2-(4-pyridylethyl)thiopropyl trimethoxy silane, bis[3-(triethoxysilyl)propyl]disulfide, 3-(triethoxysilyl)propylsuccinic anhydride, γ-mercaptopropyl trimethoxy silane, γ-mercaptopropyl triethoxy silane, isocyanatopropyl trimethoxy silane, isocyanatopropyl triethoxy silane, isocyanatoethyl triethoxy silane, isocyanatomethyl triethoxy silane, carboxyethyl silane triol sodium salt, N-(trimethoxysilylpropyl)ethylenediaminetriacetic acid trisodium salt, 3-(trihydroxysilyl)-1-propanesulfonic acid, diethyl phosphate ethyl triethoxy silane, 3-trihydroxy silyl propyl methyl phosphonate sodium salt, bis(triethoxysilyl)ethane, bis(trimethoxysilyl)ethane, bis(triethoxysilyl)methane, 1,6-bis(triethoxysilyl)hexane, 1,8-bis(triethoxysilyl)octane, p-bis(trimethoxysilylethyl)benzene, p-bis(trimethoxysilylmethyl)benzene, 3-methoxy propyl trimethoxy silane, 2-[methoxy(polyethyleneoxy)propyl]trimethoxy silane, methoxy triethyleneoxy propyl trimethoxy silane, tris(3-trimethoxysilylpropyl)isocyanurate, [hydroxy(polyethyleneoxy)propyl]triethoxy silane, N,N′-bis(hydroxyethyl)-N,N′-bis(trimethoxysilylpropyl)ethylenediamine, bis-[3-(triethoxysilylpropyl)-2-hydroxypropoxy]polyethylene oxide, bis[N,N′-(triethoxysilylpropyl)aminocarbonyl]polyethylene oxide, and bis(triethoxysilylpropyl)polyethylene oxide. Of these, particularly preferable examples include methyl trimethoxy silane, ethyl trimethoxy silane, methyl triethoxy silane, ethyl triethoxy silane, 3-glycidoxy propyl trimethoxy silane, and the like from the viewpoint of availability and the viewpoint of adhesiveness with a hydrophilic layer.

In a case in which M¹ is Si and a is 4, i.e., examples of tetrafunctional tetraalkoxy silanes include tetramethoxy silane, tetraethoxy silane, tetrapropoxy silane, tetrabutoxy silane, methoxy triethoxy silane, ethoxy trimethoxy silane, methoxy tripropoxy silane, ethoxy tripropoxy silane, propoxy trimethoxy silane, propoxy triethoxy silane, dimethoxy diethoxy silane, and the like. Of these, particularly preferable examples include tetramethoxy silane, tetraethoxy silane, and the like.

In a case in which M¹ is Ti and a is 2, i.e., examples of bifunctional organoalkoxy titanates include dimethyl dimethoxy titanate, diethyl dimethoxy titanate, propyl methyl dimethoxy titanate, dimethyl diethoxy titanate, diethyl diethoxy titanate, dipropyl diethoxy titanate, phenyl ethyl diethoxy titanate, phenyl methyl dipropoxy titanate, dimethyl dipropoxy titanate, and the like.

In a case in which M¹ is Ti and a is 3, i.e., examples of trifunctional organoalkoxy titanates include methyl trimethoxy titanate, ethyl trimethoxy titanate, propyl trimethoxy titanate, methyl triethoxy titanate, ethyl triethoxy titanate, propyl triethoxy titanate, chloromethyl triethoxy titanate, phenyl trimethoxy titanate, phenyl triethoxy titanate, phenyl tripropoxy titanate, and the like.

In a case in which M¹ is Ti and a is 4, i.e., examples of tetrafunctional alkoxy titanates include tetraalkoxy titanates such as tetramethoxy titanate, tetraethoxy titanate, tetrapropoxy titanate, tetraisopropoxy titanate, and tetrabutoxy titanate.

In a case in which M¹ is Zr and a is 2 or 3, i.e., examples of bifunctional and trifunctional organoalkoxy zirconates include organoalkoxy zirconates prepared by changing Ti in the compounds exemplified as the bifunctional and trifunctional organoalkoxy titanates to Zr.

In a case in which M¹ is Zr and a is 4, i.e., examples of tetrafunctional tetraalkoxy zirconates include zirconates prepared by changing Ti in the compounds exemplified as the tetraalkoxy titanates to Zr.

Examples of alkoxide compounds of Al, which are compounds excluded from the scope of a compound of Formula (II), include trimethoxy aluminate, triethoxy aluminate, tripropoxy aluminate, tetraethoxy aluminate, and the like.

These specific alkoxides are readily available as commercial products or are also obtained by a known synthesis method, e.g., by reaction of each metal chloride with an alcohol.

The tetraalkoxy compounds and the organoalkoxy compounds may be each used alone or may be used in combination of two or more compounds.

The sol-gel cured product includes a three-dimensional crosslinked structure including at least one selected from the group consisting of a partial structure represented by the following Formula (1), a partial structure represented by the following Formula (2), and a partial structure represented by Formula (3):

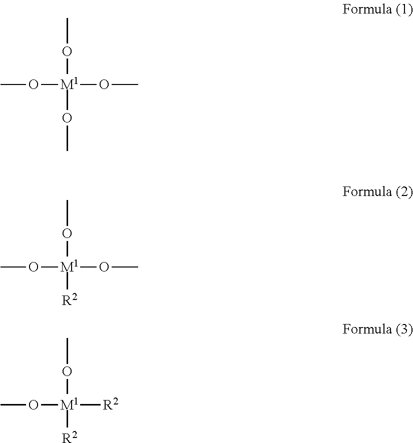

(wherein M¹ represents an element selected from the group consisting of Si, Ti, and Zr; and each R² independently represents a hydrogen atom or a hydrocarbon group).

Preferable embodiments of M¹ and R² in Formula (1) to Formula (3) are the same as the preferable embodiments of M¹ and R² in Formula (I), respectively.

It is necessary that, in the conductive layer, a content ratio of the sol-gel cured product/the metal nanowire satisfies at least any one of conditions that (i) a ratio of the substance amount of an element (b) selected from the group consisting of Si, Ti, Zr, and Al originating from an alkoxide compound as a raw material for the sol-gel cured product to the substance amount of a metal element (a) originating from the metal nanowire [(molar number of contained element (b)/molar number of contained metal element (a))] is in a range of from 0.10/1 to 22/1; and (ii) a ratio of the mass of the alkoxide compound to the mass of the metal nanowire [(content of alkoxide compound)/(content of metal nanowire)] is in a range of from 0.25/1 to 30/1. The conductive layer that has high electrical conductivity, high transparency, and high film strength and is excellent in wearing resistance, heat resistance, resistance to moist heat, and flexibility is easily obtained by satisfying any one of the conditions.

Method of Producing Conductive Member

In one embodiment, the conductive member can be produced by a method including at least coating a base material with a liquid composition (hereinafter also referred to as “sol-gel coating liquid”) including the metal nanowire having an average minor axis length of 150 nm or less and the specific alkoxide compound so that the mass ratio thereof (i.e., (content of specific alkoxide compound)/(content of metal nanowire)) is in a range of from 0.25/1 to 30/1 or a mass ratio of a contained element (b) originating from the specific alkoxide compound to a contained metal element (a) originating from the metal nanowire is in a range of from 0.10/1 to 22/1, to form a liquid film; and forming a conductive layer by effecting a reaction of hydrolysis and polycondensation of the specific alkoxide compound in the liquid film (hereinafter the reaction of hydrolysis and polycondensation is also referred to as “sol-gel reaction”). The method may or may not further include evaporating (drying) water, which can be contained as a solvent in the liquid composition, by heating if necessary.

In one embodiment, the sol-gel coating liquid may also be produced by preparing an aqueous dispersion of the metal nanowire and mixing the aqueous dispersion with the specific alkoxide compound. In one embodiment, the sol-gel coating liquid may also be prepared by preparing an aqueous solution containing the specific alkoxide compound, heating the aqueous solution to hydrolyze and polycondense at least a part of the specific alkoxide compound to be in a sol state and by mixing the aqueous solution in the sol state with an aqueous dispersion of the metal nanowire.

It is practically preferable to use an acid catalyst or a basic catalyst together in order to accelerate the sol-gel reaction since reaction efficiency can be enhanced. The catalyst is explained below.

[Catalyst]

The liquid composition for forming the conductive layer preferably includes at least one catalyst that accelerates the sol-gel reaction. The catalyst is not particularly limited, as long as the catalyst accelerates the reaction of hydrolysis and polycondensation of the tetraalkoxy and organoalkoxy compounds, and can be appropriately selected from commonly used catalysts and be used.

Examples of such catalysts include acidic compounds and basic compounds. They may be directly used as they are or may be used in the state of being dissolved in a solvent such as water or alcohol (hereinafter they are also collectively referred to as acid catalysts and basic catalysts, respectively).

A concentration at which the acidic compound or the basic compound is dissolved in a solvent is not particularly limited and may be appropriately selected depending on the characteristics of the acidic or basic compound used, the desired content of a catalyst, and the like. In a case in which the concentration of the acidic or basic compound that constitutes the catalyst is high, a hydrolysis and polycondensation rate tends to be high. In the case of using a basic catalyst, its concentration is desirably 1 N or less on the basis of concentration in a liquid composition, since a precipitate may be generated to cause a defect in the conductive layer by using a basic catalyst having excessively high concentration.

The kind of the acid catalyst or the basic catalyst is not particularly limited. In the case of requiring use of a catalyst with high concentration, it is preferable to select a catalyst formed of an element that hardly remains in the conductive layer. Specific examples of acid catalysts include inorganic acids such as hydrogen halides such as hydrochloric acid, nitric acid, sulfuric acid, sulfurous acid, hydrogen sulfide, perchloric acid, hydrogen peroxide, and carbonic acid; carboxylic acids such as formic acid and acetic acid; substituted carboxylic acids having the structural formula represented by RCOOH in which R has a substituent; sulfonic acids such as benzenesulfonic acid; and the like. Examples of basic catalysts include ammoniacal base materials such as ammonia water; organic amines such as ethylamine and aniline; and the like.

R represents a hydrocarbon group. The hydrocarbon group represented by R has the same definition as that of the hydrocarbon group in Formula (II) and a preferable embodiment thereof is also the same.

As the catalyst, a Lewis acid catalyst including a metal complex can also be preferably used. Particularly preferable catalysts are metal complex catalysts and are metal complexes constituted by metal elements selected from Groups 2A, 3B, 4A, and 5A in the periodic table and ligands which are oxo or hydroxy oxygen-containing compounds selected from the group consisting of β-diketone, ketoesters, hydroxycarboxylic acids or esters thereof, amino alcohols, and enolic active hydrogen compounds.

Of the constituent metal elements, Group 2A elements such as Mg, Ca, St, and Ba, Group 3B elements such as Al and Ga, Group 4A element such as Ti and Zr, and Group 5A elements such as V, Nb, and Ta are preferable and each form complexes having an excellent catalytic effect. Of these, complexes including metal elements selected from the group consisting of Zr, Al, and Ti are excellent and preferable.

In accordance with the present invention, examples of the oxo or hydroxy oxygen-containing compound that constitutes the ligand of the metal complex include β-diketones such as acetylacetone(2,4-pentanedione) and 2,4-heptanedione; ketoesters such as methyl acetoacetate, ethyl acetoacetate, and butyl acetoacetate; hydroxycarboxylic acids, such as lactic acid, methyl lactate, salicylic acid, ethyl salicylate, phenyl salicylate, malic acid, tartaric acid, and methyl tartrate, and esters thereof; keto alcohols such as 4-hydroxy-4-methyl-2-pentanone, 4-hydroxy-2-pentanone, 4-hydroxy-4-methyl-2-heptanone, and 4-hydroxy-2-heptanone; amino alcohols such as monoethanolamine, N,N-dimethyl ethanolamine, N-methyl-monoethanolamine, diethanolamine, and triethanolamine; enolic active compounds such as methylol melamine, methylol urea, methylolacrylamide, and diethyl malonate ester; and compounds such as an acetylacetone derivative having a substituent on the methyl group, methylene group or carbonyl carbon of acetylacetone(2,4-pentanedione).

A preferable ligand is an acetylacetone derivative. As used herein, the acetylacetone derivative refers to a compound having a substituent on the methyl group, methylene group or carbonyl carbon of acetylacetone. Examples of the substituent on the methyl group of acetylacetone include straight or branched alkyl, acyl, hydroxyalkyl, carboxyalkyl, alkoxy and alkoxyalkyl groups each having a carbon number of 1 to 3; examples of the substituent on the methylene group of acetylacetone include a carboxyl group and straight or branched carboxyalkyl and hydroxyalkyl groups each having a carbon number of 1 to 3; and examples of the substituent on the carbonyl carbon of acetylacetone include an alkyl group having a carbon number of 1 to 3, and in this case, a hydrogen atom is added to the carbonyl oxygen to form a hydroxyl group.

Specific preferable examples of the acetylacetone derivative include ethylcarbonylacetone, n-propylcarbonylacetone, i-propylcarbonylacetone, diacetylacetone, 1-acetyl-1-propionyl-acetylacetone, hydroxyethylcarbonylacetone, hydroxypropylcarbonylacetone, acetoacetic acid, acetopropionic acid, diacetoacetic acid, 3,3-diacetopropionic acid, 4,4-diacetobutyric acid, carboxyethylcarbonylacetone, carboxypropylcarbonylacetone, and diacetone alcohol. Among these, acetylacetone and diacetylacetone are particularly preferable. The complex of the acetylacetone derivative with the metal element is a mononuclear complex in which 1 to 4 acetylacetone derivative molecules are coordinated per one metal element, and in a case in which the number of coordination bonds of the metal element is greater than the total number of coordination bonds of acetylacetone derivatives, the metal element may be coordinated with a ligand commonly used in a normal complex, such as water molecule, halogen ion, nitro group, or ammonio group.

Preferable examples of the metal complex include a tris(acetylacetonato)aluminum complex salt, a di(acetylacetonato)aluminum-aquo-complex salt, a mono(acetylacetonato)aluminum-chloro-complex salt, a di(diacetylacetonato)aluminum complex salt, an ethylacetoacetate aluminum diisopropylate, an aluminum tris(ethylacetoacetate), a cyclic aluminum oxide isopropylate, a tris(acetylacetonato)barium complex salt, a di(acetylacetonato)titanium complex salt, a tris(acetylacetonato)titanium complex salt, a di-i-propoxy-bis(acetylacetonato)titanium complex salt, a zirconium tris(ethylacetoacetate), a zirconium tris(benzoate) complex salt, and the like. These compounds exhibit excellent stability in an aqueous coating liquid and provide an excellent effect of accelerating gelling in the sol-gel reaction during drying by heating; and among these, an ethylacetoacetate aluminum diisopropylate, an aluminum tris(ethylacetoacetate), a di(acetylacetonato)titanium complex salt, and a zirconium tris(ethylacetoacetate) are particularly preferable.

Detailed description of the counter salt of the above-described metal complex is herein omitted. The metal complex may have an arbitrary kind of a counter salt as long as it is a water-soluble salt capable of keeping the charge neutrality as a complex compound, and for example, a salt form ensuring stoichiometric neutrality, such as nitrate, halogen acid salt, sulfate and phosphate, is used.

The behavior of the metal complex in a silica sol-gel reaction is described in detail in J. Sol-Gel. Sci. and Tec., vol. 16, pp. 209-220 (1999). The reaction mechanism is presumed as being the following scheme. That is, the metal complex in a liquid composition is stable by taking on a coordination structure. In a dehydrating condensation reaction started in natural drying or the process of heating and drying after application to a base material, crosslinking is considered to be accelerated by the mechanism like an acid catalyst. In any way, by virtue of using this metal complex, stability with aging of the liquid composition and the film surface quality and high durability of the conductive layer can be excellent.

The above-described metal complex catalyst is readily available as a commercial product or is also obtained by a known synthesis method, e.g., by reaction of each metal chloride with an alcohol.

In a case in which the liquid composition contains a catalyst, the catalyst is preferably used in a range of from 50 mass % or less, further preferably 5 mass % to 25 mass %, based on the solid content of the liquid composition. The catalyst may be used alone or in combination of two or more kinds.

[Solvent]

The above-described liquid composition may or may not include water and/or an organic solvent. A more uniform liquid film can be formed on the base material by including the organic solvent.

Examples of such organic solvents include ketone solvents such as acetone, methyl ethyl ketone, and diethyl ketone; alcohol solvents such as methanol, ethanol, 2-propanol, 1-propanol, 1-butanol, and tert-butanol; chlorine solvents such as chloroform and methylene chloride; aromatic solvents such as benzene and toluene; ester solvents such as ethyl acetate, butyl acetate, and isopropyl acetate; ether solvents such as diethyl ether, tetrahydrofuran, and dioxane; glycol ether solvents such as ethylene glycol monomethyl ether and ethylene glycol dimethyl ether; and the like.

In a case in which the liquid composition include the organic solvent, the organic solvent is preferably 50 mass % or less, further more preferably in a range of from 30 mass % or less, based on the total mass of the liquid composition.

A reaction of hydrolysis and condensation of the specific alkoxide compound occurs in a coating liquid film of a sol-gel coating liquid formed on a base material and it is preferable to heat and dry the coating liquid film in order to accelerate the reaction. A heating temperature for accelerating the sol-gel reaction is suitably in a range of from 30° C. to 200° C., more preferably in a range of from 50° C. to 180° C. A heating and drying time is preferably 10 seconds to 300 minutes, more preferably 1 minute to 120 minutes.

The average film thickness of the conductive layer is usually selected in a range of from 0.005 μm to 2 μm. For example, the average film thickness of from 0.001 μm to 0.5 μm or less can result in sufficient durability and film strength and further in suppression of generation of a conductive fiber residue in the non-conductive part in a case in which the conductive layer is divided into a conductive section and a non-conductive section by patterning. In particular, the average film thickness in a range of from 0.01 μm to 0.1 μm is preferable since a range permissible for production can be secured.

The present invention enables, by satisfying at least one of the above-described (i) or (ii) in the conductive layer, to maintain high electrical conductivity and transparency, and by having the sol-gel cured product in the conductive layer, to stably fix the metal nanowire and to realize high strength and durability d. For example, a conductive member having wearing resistance, heat resistance, resistance to moist heat, and flexing resistance without any problem with regard to practical use can be obtained even if the conductive layer is a thin layer having a film thickness of 0.005 μm to 0.5 μm. Therefore, the conductive member which is one embodiment of the present invention is preferably used for various uses. In an embodiment in which the conductive layer as a thin layer is needed, the film thickness may be in a range of from 0.005 μm to 0.5 μm, further preferably in a range of from 0.007 μm to 0.3 μm, more preferably in a range of from 0.008 μm to 0.2 μm, and most preferably in a range of from 0.01 μm to 0.1 μm. The effect of suppressing residual conductive fibers in the non-conductive section at the time of patterning and the transparency of the conductive layer can be further improved by making the conductive layer as a thinner layer as described above.

The average film thickness of the conductive layer is calculated by measuring the film thicknesses of five points of the conductive layer by direct observation of the cross section of the conductive layer with an electron microscope and by determining the arithmetic mean value thereof. In addition, the film thickness of the conductive layer can be measured as a level difference between a portion where the conductive layer is formed and a portion where the conductive layer is removed, for example, using a probe-type surface shape measuring device (DEKTAK (registered trademark) 150, manufactured by Bruker AXS). However, since a portion of the base material may be further removed in the case of the removal of the conductive layer, an error is easy to occur because the formed conductive layer is thin. Therefore, average film thicknesses measured using an electron microscope are described in Examples described below.

In the conductive layer, a water drop contact angle on the surface (hereinafter also referred to as “front surface”) opposite to a surface facing the base material is preferably from 3° to 70°. The angle is more preferably from 5° to 60°, further preferably from 5° to 50°, and most preferably from 5° to 40°. If the water drop contact angle on the surface of the conductive layer is in this range, an etching rate tends to be improved in a patterning method using an etching liquid mentioned below. This can be considered to be because, for example, the etching liquid is easily taken in the conductive layer. Further, the accuracy of the line width of a thin line tends to be improved in the case of patterning. Furthermore, in a case in which a wiring line is formed with silver paste on the conductive layer, adhesiveness between the conductive layer and the silver paste tends to be improved.

In addition, a water drop contact angle on the front surface of the conductive layer is measured using a contact angle meter (e.g., fully automatic contact angle meter, trade name: DM-701, manufactured by Kyowa Interface Science Co., Ltd.) at 25° C.

A water drop contact angle on the surface of the conductive layer can be made to be in a desired range, for example, by appropriately selecting the kind of an alkoxide compound in a liquid composition, the condensation degree of alkoxide, the smoothness of electrical conductivity, and the like.

<Matrix>

The conductive layer may include a matrix. Herein, “matrix” is the generic term of a substance which forms a layer by including metal nanowires. By the inclusion of the matrix, the dispersion of the metal nanowires in the conductive layer is stably maintained, and firm adhesion between the base material and the conductive layer tends to be secured even in the case of forming the conductive layer on the surface of the base material via no adhesive layer. Although the sol-gel cured product contained in the conductive layer also has a function as a matrix, the conductive layer may also further include a matrix other than the sol-gel cured product (hereinafter referred to as an “additional matrix”). The conductive layer including the additional matrix may be formed by incorporating a material capable of forming the additional matrix into the above-mentioned liquid composition and applying the liquid composition onto the base material (for example, by coating).

The additional matrix may be a non-photosensitive matrix such as an organic high-molecular-weight polymer or a photosensitive matrix such as a photoresist composition.

In a case in which the conductive layer includes the additional matrix, it is advantageous that the content thereof is selected from the range of from 0.10 mass % to 20 mass %, preferably from 0.15 mass % to 10 mass %, and further preferably from 0.20 mass % to 5 mass %, based on the content of the sol-gel cured product originating from the specific alkoxy compound contained in the conductive layer, since a conductive member excellent in electrical conductivity, transparency, film strength, wearing resistance, and flexing resistance is obtained.

The additional matrix may be non-photosensitive or photosensitive as mentioned above.

Preferable examples of the non-photosensitive matrix include an organic high-molecular-weight polymer. Specific examples of the organic high-molecular-weight polymer include polyacrylic acids such as polymethacrylic acid, polymethacrylates (e.g., poly(methyl methacrylate)), polyacrylates, and polyacrylonitrile; polymers having high aromaticness, such as polyvinyl alcohol, polyesters (e.g., polyethylene terephthalate (PET), polyethylene naphthalate and polycarbonate), phenol- or cresol-formaldehyde (NOVOLACS (registered trademark)), polystyrene, polyvinyl toluene, polyvinyl xylene, polyimide, polyamide, polyamide-imide, polyetherimide, polysulfide, polysulfone, polyphenylene, and polyphenyl ether; polyurethane (PU), epoxy, polyolefin (e.g., polypropylene, polymethylpentene, and cyclic olefin), acrylonitrile-butadiene-styrene copolymer (ABS), cellulose, silicone and other silicon-containing polymers (e.g., polysilsesquioxane and polysilane), polyvinyl chloride (PVC), polyvinyl acetate, polynorbornene, synthetic rubber (e.g., EPR, SBR, EPDM), and fluorocarbon polymers (e.g., polyvinylidene fluoride, polytetrafluoroethylene (PTFE), or polyhexafluoropropylene), fluoro-olefin copolymer, and hydrocarbon olefin (e.g., “LUMIFLON” (registered trademark) manufactured by ASAHI GLASS CO., LTD.), and amorphous fluorocarbon polymers or copolymers (e.g., “CYTOP” (registered trademark) manufactured by ASAHI GLASS CO., LTD. or “Teflon” (registered trademark) AF manufactured by DuPont), but are not limited only thereto.

The photosensitive matrix may include a photoresist composition preferable for a lithographic process. In a case in which a photoresist composition is included as a matrix, a conductive layer having a conductive region and a non-conductive region on a pattern can be formed by a lithographic process. Particularly preferable examples of such photoresist compositions include a photopolymerizable composition in view of obtaining a conductive layer excellent in transparency and softness and in adhesiveness with a base material. The photopolymerizable composition is explained below.

### <Photopolymerizable Composition>

The photopolymerizable composition includes, as fundamental components, (a) an addition-polymerizable unsaturated compound, and (b) a photopolymerization initiator that generates radicals by being irradiated with light. The photopolymerizable composition may further include (c) a binder and/or (d) an additive other than the above-described constituents (a) to (c), as desired.

These components are explained below.

[(a) Addition-Polymerizable Unsaturated Compound]

The addition-polymerizable unsaturated compound as the component (a) (hereinafter also referred to as “polymerizable compound”) is a compound polymerized by an addition polymerization reaction in the presence of a radical and a compound having at least one, preferably two or more, more preferably four or more, and further preferably six or more, unsaturated ethylenic double bonds on a molecular end is usually used.

They have chemical form such as, for example, a monomer, a prepolymer, i.e., a dimer, a trimer or an oligomer, or a mixture thereof.

As such polymerizable compounds, various compounds are known, and they can be used as the component (a).

Of these, particularly preferable examples of the polymerizable compounds include trimethylolpropane tri(meth)acrylate, pentaerythritol tetra(meth)acrylate, dipentaerythritol hexa(meth)acrylate, and dipentaerythritol penta(meth)acrylate from the viewpoint of film strength.

The content of the component (a) in the conductive layer is preferably from 2.6 mass % to 37.5 mass %, and more preferably from 5.0 mass % to 20.0 mass %, on the basis of the total mass of the solid content of the photopolymerizable composition containing the above-mentioned metal nanowire.

[(b) Photopolymerization Initiator]

The photopolymerization initiator as the component (b) is a compound that generates radicals by being irradiated with light. Examples of such photopolymerization initiators include a compound that generates an acid radical that finally becomes an acid by light irradiation; a compound that generates other radicals; and the like. Hereinafter, the former is referred to as “photo-acid generator” while the latter is referred to as “photo-radical generator”.

### —Photo-Acid Generator—

As the photo-acid generator, a photoinitiator for photo-cationic polymerization, a photoinitiator for photo-radical polymerization, a photo-decolorizing agent for pigments, a photo-discoloration agent, or a known compounds that is used in a micro-resist or the like and generates acid radicals by irradiation with active light rays or radioactive rays, and a mixture thereof can be appropriately selected and be used.

Such a photo-acid generator is not particularly limited and can be appropriately selected depending on a purpose without particular limitation, and examples thereof include triazine or 1,3,4-oxadiazole having at least one di- or tri-halomethyl group, naphthoquinone-1,2-diazide-4-sulfonyl halide, diazonium salts, phosphonium salts, sulfonium salts, iodonium salts, imide sulfonate, oxime sulfonate, diazodisulfone, disulfone, o-nitrobenzylsulfonate, and the like. Of these, imide sulfonate, oxime sulfonate, and o-nitrobenzylsulfonate which are compounds that generate sulfonic acid are particularly preferable.

Further, a compound in which a group or compound that generates an acid radical by irradiation with active light rays or radioactive rays is introduced into the main or side chain of a resin can be used. Examples thereof include a compound described in, e.g., each of U.S. Pat. No. 3,849,137, German Patent No. 3914407, Japanese Patent Application Laid-Open (JP-A) No. S63-26653, Japanese Patent Application Laid-Open (JP-A) No. S55-164824, Japanese Patent Application Laid-Open (JP-A) No. S62-69263, Japanese Patent Application Laid-Open (JP-A) No. S63-146038, Japanese Patent Application Laid-Open (JP-A) No. S63-163452, Japanese Patent Application Laid-Open (JP-A) No. S62-153853, and Japanese Patent Application Laid-Open (JP-A) No. S63-146029.

Furthermore, a compound described in each of U.S. Pat. No. 3,779,778, European Patent No. 126,712, and the like can also be used as an acid radical generator.

Examples of the triazine compound include 2-(4-methoxyphenyl)-4,6-bis(trichloromethyl)-s-triazine, 2-(4-methoxynaphthyl)-4,6-bis(trichloromethyl)-s-triazine, 2-(4-ethoxynaphthyl)-4,6-bis(trichloromethyl)-s-triazine, 2-(4-ethoxycarbonylnaphthyl)-4,6-bis(trichloromethyl)-s-triazine, 2,4,6-tris(monochloromethyl)-s-triazine, 2,4,6-tris(dichloromethyl)-s-triazine, 2,4,6-tris(trichloromethyl)-s-triazine, 2-methyl-4,6-bis(trichloromethyl)-s-triazine, 2-n-propyl-4,6-bis(trichloromethyl)-s-triazine, 2-(α,α,β-trichloroethyl)-4,6-bis(trichloromethyl)-s-triazine, 2-phenyl-4,6-bis(trichloromethyl)-s-triazine, 2-(p-methoxyphenyl)-4,6-bis(trichloromethyl)-s-triazine, 2-(3,4-epoxyphenyl)-4,6-bis(trichloromethyl)-s-triazine, 2-(p-chlorophenyl)-4,6-bis(trichloromethyl)-s-triazine, 2-[1-(p-methoxyphenyl)-2,4-butadienyl]-4,6-bis(trichloromethyl)-s-triazine, 2-styryl-4,6-bis(trichloromethyl)-s-triazine, 2-(p-methoxystyryl)-4,6-bis(trichloromethyl)-s-triazine, 2-(p-i-propyloxystyryl)-4,6-bis(trichloromethyl)-s-triazine, 2-(p-tolyl)-4,6-bis(trichloromethyl)-s-triazine, 2-(4-methoxynaphthyl)-4,6-bis(trichloromethyl)-s-triazine, 2-phenylthio-4,6-bis(trichloromethyl)-s-triazine, 2-benzylthio-4,6-bis(trichloromethyl)-s-triazine, 4-(o-bromo-p-N,N-bis(ethoxycarbonylamino)-phenyl)-2,6-di(trichloromethyl)-s-triazine, 2,4,6-tris(dibromomethyl)-s-triazine, 2,4,6-tris(tribromomethyl)-s-triazine, 2-methyl-4,6-bis(tribromomethyl)-s-triazine, 2-methoxy-4,6-bis(tribromomethyl)-s-triazine, and the like. They may be used alone or in combination of two or more kinds.

Among the photo-acid generators (1), compounds that generate sulfonic acid are preferable, and oxime sulfonate compounds such as those described below are particularly preferable from the viewpoint of high sensitivity.

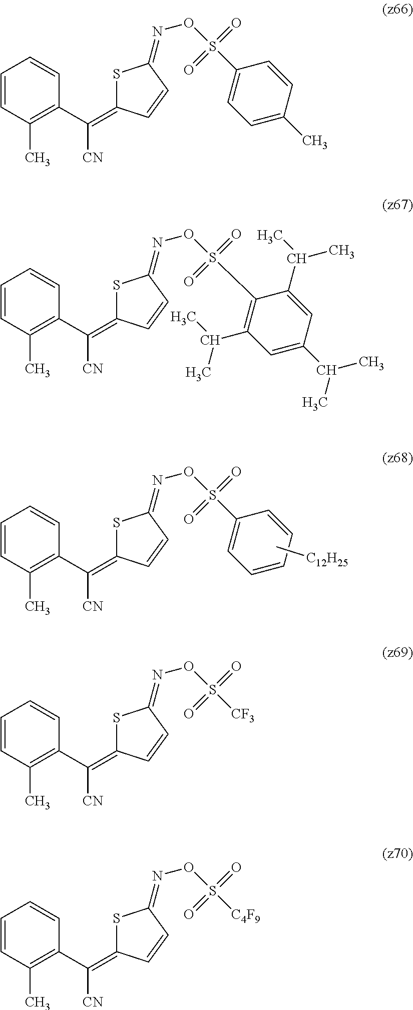

—Photo-Radical Generator—

The photo-radical generator is a compound having the function of directly absorbing light or being subjected to photosensitization to cause a decomposition reaction or a hydrogen abstraction reaction to generate radicals. The photo-radical generator preferably has absorption in the region of wavelengths of from 300 nm to 500 nm.

As such photo-radical generators, a large number of compounds are known, and examples thereof include carbonyl compounds, ketal compounds, benzoin compounds, acridine compounds, organic peroxide compounds, azo compounds, coumarin compounds, azide compounds, metallocene compounds, hexaarylbiimidazole compounds, organic boric acid compounds, disulfonic acid compounds, oxime ester compounds, and acyl phosphine (oxide) compounds, as described in Japanese Patent Application Laid-Open (JP-A) No. 2008-268884. These can be appropriately selected depending on a purpose. Of these, benzophenone compounds, acetophenone compounds, hexaarylbiimidazole compounds, oxime ester compounds, and acyl phosphine (oxide) compounds are particularly preferable from the viewpoint of exposure sensitivity.

Examples of the benzophenone compounds include benzophenone, Michler's ketone, 2-methylbenzophenone, 3-methylbenzophenone, N,N-diethylaminobenzophenone, 4-methylbenzophenone, 2-chlorobenzophenone, 4-bromobenzophenone, 2-carboxybenzophenone, and the like. They may be used alone or in combination of two or more kinds.

Examples of the acetophenone compounds include 2,2-dimethoxy-2-phenylacetophenone, 2,2-diethoxyacetophenone, 2-(dimethylamino)-2-[(4-methylphenyl)methyl]-1-[4-(4-morpholinyl)phenyl]-1-butanone, 1-hydroxycyclohexylphenylketone, α-hydroxy-2-methylphenylpropanone, 1-hydroxy-1-methylethyl(p-isopropylphenyl)ketone, 1-hydroxy-1-(p-dodecylphenyl)ketone, 2-methyl-1-(4-methylthiophenyl)-2-morpholinopropane-1-one, 1,1,1-trichloromethyl-(p-butylphenyl)ketone, 2-benzyl-2-dimethylamino-1-(4-morpholinophenyl)-butanone-1, and the like. As specific examples of commercial products, IRGACURE (registered trademark) 369, IRGACURE (registered trademark) 379, and IRGACURE (registered trademark) 907 manufactured by BASF AG, and the like are preferable. They may be used alone or in combination of two or more kinds.

Examples of the hexaarylbiimidazole compounds include various compounds described in each of Japanese Patent Publication (JP-A) No. H6-29285, U.S. Pat. No. 3,479,185, U.S. Pat. No. 4,311,783, U.S. Pat. No. 4,622,286, and the like, specifically, 2,2′-bis(o-chlorophenyl)-4,4′,5,5′-tetraphenylbiimidazole, 2,2′-bis(o-bromophenyl)-4,4′,5,5′-tetraphenylbiimidazole, 2,2′-bis(o,p-dichlorophenyl)-4,4′,5,5′-tetraphenylbiimidazole, 2,2′-bis(o-chlorophenyl)-4,4′,5,5′-tetra(m-methoxyphenyl)biimidazole, 2,2′-bis(o,o′-dichlorophenyl)-4,4′,5,5′-tetraphenylbiimidazole, 2,2′-bis(o-nitrophenyl)-4,4′,5,5′-tetraphenylbiimidazole, 2,2′-bis(o-methylphenyl)-4,4′,5,5′-tetraphenylbiimidazole, 2,2′-bis(o-trifluorophenyl)-4,4′,5,5′-tetraphenylbiimidazole, and the like. They may be used alone or in combination of two or more kinds.

Examples of the oxime ester compounds include compounds described in J. C. S. Perkin II (1979) 1653-1660, J. C. S. Perkin 11 (1979) 156-162, Journal of Photopolymer Science and Technology (1995) 202-232, and Japanese Patent Application Laid-Open (JP-A) No. 2000-66385; compounds described in Japanese Patent Application Laid-Open (JP-A) No. 2000-80068 and Japanese National Phase Publication (JP-A) No. 2004-534797; and the like. As specific examples, IRGACURE (registered trademark) OXE-01 and IRGACURE (registered trademark) OXE-02 manufactured by BASF AG; and the like are preferable. They may be used alone or in combination of two or more kinds.

Examples of the acyl phosphine (oxide) compounds include IRGACURE (registered trademark) 819, DAROCUR (registered trademark) 4265, and DAROCUR (registered trademark) TPO manufactured by BASF AG; and the like.

As such photo-radical generators, 2-(dimethylamino)-2-[(4-methylphenyl)methyl]-1-[4-(4-morpholinyl)phenyl]-1-butanone, 2-benzyl-2-dimethylamino-1-(4-morpholinophenyl)-butanone-1, 2-methyl-1-(4-methylthiophenyl)-2-morpholinopropane-1-one, 2,2′-bis(2-chlorophenyl)-4,4′,5,5′-tetraphenylbiimidazole, N,N-diethylaminobenzophenone, 1,2-octanedione, and 1-[4-(phenylthio)phenyl]-1,2-octanedione2-(o-benzoyloxime) are particularly preferable from the viewpoint of exposure sensitivity and transparency.

The photopolymerization initiator as the component (b) may be used alone or in combination of two or more kinds and the content thereof in the conductive layer is preferably from 0.1 mass % to 50 mass %, more preferably from 0.5 mass % to 30 mass %, and further preferably 1 mass % to 20 mass %, on the basis of total mass of the solid content of the photopolymerizable composition containing metal nanowires. In a case in which a pattern including a conductive region and a non-conductive region described below is formed on the conductive layer in such a numerical value range, good sensitivity and pattern formation properties may be obtained.

[(c) Binder]

The binder can be appropriately selected from alkali-soluble resins that are linear organic high-molecular-weight polymers and have at least one group that enhances alkali-solubility (e.g., a carboxyl group, a phosphate group, a sulfonic acid group, or the like) in the molecule (preferably a molecule of which the main chain is an acrylic copolymer or a styrenic copolymer).

Of these, binders that are soluble in an organic solvent and are soluble in an alkali aqueous solution are preferable, and binders that have an acid-dissociable group and become alkali-soluble when the acid-dissociable group is dissociated by action of an acid are particularly preferable.

Herein, the acid-dissociable group represents a functional group that can be dissociated in the presence of an acid.

A method such as a known radical polymerization method can be applied to the production of the binder. Polymerization conditions such as temperature, pressure, the kind and amount of a radical initiator, and the kind of a solvent in the case of producing an alkali-soluble resin by the radical polymerization method can be easily set by those skilled in the art and the conditions can be experimentally established.

The linear organic high-molecular-weight polymer is preferably a polymer having a carboxylic acid in a side chain.

Examples of the polymer having a carboxylic acid in a side chain include methacrylic acid copolymers, acrylic acid copolymers, itaconic acid copolymers, crotonic acid copolymers, maleic acid copolymers, partially esterified maleic acid copolymers, and the like, as described in each of Japanese Patent Application Laid-Open (JP-A) No. S59-44615, Japanese National Phase Publication (JP-A) No. S54-34327, Japanese National Phase Publication (JP-A) No. S58-12577, Japanese National Phase Publication (JP-A) No. S54-25957, Japanese Patent Application Laid-Open (JP-A) No. S59-53836, and Japanese Patent Application Laid-Open (JP-A) No. S59-71048; acid cellulose derivatives having a carboxylic acid in a side chain; polymers in which an acid anhydride is added to a polymer having a hydroxyl group; and the like, and preferable examples further include high-molecular-weight polymers having a (meth)acryloyl group in a side chain.

Of these, a benzyl(meth)acrylate/(meth)acrylic acid copolymer and multicomponent copolymers including benzyl(meth)acrylate/(meth)acrylic acid/other monomer(s) are particularly preferable.

Furthermore, examples of the polymer which are useful also include high-molecular-weight polymers having a (meth)acryloyl group in a side chain and multicomponent copolymers including (meth)acrylic acid/glycidyl(meth)acrylate/other monomer(s). The polymer may be mixed in an arbitrary amount and used.

In addition to the above, further examples include a 2-hydroxypropyl(meth)acrylate/polystyrene macromonomer/benzyl methacrylate/methacrylic acid copolymer, a 2-hydroxy-3-phenoxypropyl acrylate/polymethyl methacrylate macromonomer/benzyl methacrylate/methacrylic acid copolymer, a 2-hydroxyethyl methacrylate/polystyrene macromonomer/methyl methacrylate/methacrylic acid copolymer, and a 2-hydroxyethyl methacrylate/polystyrene macromonomer/benzyl methacrylate/methacrylic acid copolymer which are described in Japanese Patent Application Laid-Open (JP-A) No. H7-140654.

Preferable specific examples of constitutional units in the alkali soluble resin are (meth)acrylic acid and other monomer(s) copolymerizable with the (meth)acrylic acid.

Examples of the other monomers copolymerizable with (meth)acrylic acid include alkyl(meth)acrylates, aryl(meth)acrylates, vinyl compounds, and the like. In the monomers, a hydrogen atom of the alkyl group and a hydrogen atom of the aryl group may be substituted by a substituent.

Examples of the alkyl(meth)acrylates or the aryl(meth)acrylates include methyl(meth)acrylate, ethyl(meth)acrylate, propyl(meth)acrylate, butyl(meth)acrylate, isobutyl(meth)acrylate, pentyl(meth)acrylate, hexyl(meth)acrylate, octyl(meth)acrylate, phenyl(meth)acrylate, benzyl(meth)acrylate, tolyl(meth)acrylate, naphthyl(meth)acrylate, cyclohexyl(meth)acrylate, dicyclopentanyl(meth)acrylate, dicyclopentenyl(meth)acrylate, dicyclopentenyloxyethyl(meth)acrylate, glycidyl methacrylate, tetrahydrofurfuryl methacrylate, polymethyl methacrylate macromonomer, and the like. They may be used alone or in combination of two or more kinds.

Examples of the vinyl compounds include styrene, α-methylstyrene, vinyltoluene, acrylonitrile, vinyl acetate, N-vinylpyrrolidone, polystyrene macromonomer, CH₂═CR¹R² [wherein R¹ represents a hydrogen atom or an alkyl group having 1 to 5 carbon atoms; and R² represents an aromatic hydrocarbon ring having 6 to 10 carbon atoms], and the like. They may be used alone or in combination of two or more kinds.

The weight average molecular weight of the binder is preferably from 1,000 to 500,000, more preferably from 3,000 to 300,000, and further preferably from 5,000 to 200,000, in view of an alkali dissolution rate, the physical properties of a film, and the like.

The weight average molecular weight can be measured by a gel permeation chromatography method and can be determined using a standard polystyrene calibration curve.

The content of the binder as the component (c) in the conductive layer is preferably from 5 mass % to 90 mass %, more preferably from 10 mass % to 85 mass %, and further preferably from 20 mass % to 80 mass %, on the basis of the total mass of the solid content of the photopolymerizable composition containing the above-mentioned metal nanowires. The preferable content range can result in both of developability and the electrical conductivity of the metal nanowires.

[(d) Other Additives Except Components (a) to (c)]

Examples of other additives except the components (a) to (c) include various additives such as a chain transfer agent, a crosslinking agent, a dispersing agent, a solvent, a surfactant, an oxidation inhibitor, a sulfuration inhibitor, a metal corrosion inhibitor, a viscosity modifier, and an antiseptic agent.

(d-1) Chain Transfer Agent

The chain transfer agent is used for improving the exposure sensitivity of a photopolymerizable composition. Examples of such chain transfer agents include N,N-alkyl dialkylaminobenzoate esters such as N,N-ethyl dimethylaminobenzoate ester; mercapto compounds having a heterocyclic ring, such as 2-mercaptobenzothiazole, 2-mercaptobenzoxazole, 2-mercaptobenzimidazole, N-phenylmercaptobenzimidazole, and 1,3,5-tris(3-mercaptobutyloxyethyl)-1,3,5-triazine-2,4,6(1H,3H,5H)-trione; aliphatic polyfunctional mercapto compounds such as pentaerythritol tetrakis(3-mercaptopropionate), pentaerythritol tetrakis(3-mercaptobutyrate), and 1,4-bis(3-mercaptobutyryloxy)butane; and the like. They may be used alone or in combination of two or more kinds.

The content of the chain transfer agent in the conductive layer is preferably from 0.01 mass % to 15 mass %, from more preferably 0.1 mass % to 10 mass %, and from further preferably 0.5 mass % to 5 mass %, on the basis of the total mass of the solid content of the photopolymerizable composition including the above-mentioned metal nanowires.

(d-2) Crosslinking Agent

The crosslinking agent is a compound that forms free radicals or a chemical bond by acid and heat to cure a conductive layer and examples include melamine compounds, guanamine compounds, glycoluril compounds, urea compounds, phenol compounds or phenolic ether compounds, epoxy compounds, oxetane compounds, thioepoxy compounds, isocyanate compounds, or azido compounds, substituted by at least one selected from a methylol group, an alkoxymethyl group, and an acyloxymethyl group; compounds having an ethylenically unsaturated group including a methacryloyl group, an acryloyl group, or the like; and the like. Of these, epoxy compounds, oxetane compounds, and compounds having an ethylenically unsaturated group are particularly preferable in view of the physical properties of a film, heat resistance, and solvent resistance.

The oxetane resin may be used alone or in admixture with an epoxy resin. In particular, the epoxy resin is preferably used in combination therewith from the viewpoint of high reactivity and improvement in the physical properties of a film.

In the case of using the compound having an unsaturated ethylenic double bond group as a crosslinking agent, it should be considered that the crosslinking agent is also encompassed by the polymerizable compound (c) and the content thereof is included in the content of the polymerizable compound (c).

The content of the crosslinking agent in the conductive layer is preferably from 1 part by mass to 250 parts by mass, and more preferably from 3 parts by mass to 200 parts by mass, assuming that the total mass of the solid content of the photopolymerizable composition including the above-mentioned metal nanowires is 100 parts by mass.

(d-3) Dispersing Agent

The dispersing agent is used for dispersing the above-mentioned metal nanowires in the photopolymerizable composition while supressing the metal nanowire from agglomerating. The dispersing agent is not particularly limited as long as the metal nanowires can be dispersed, and can be suitably selected depending on a purpose. For example, dispersing agents commercially available as pigment dispersing agents can be used and a high-molecular dispersing agent having the properties of being adsorbed in metal nanowires is particularly preferable. Examples of such high-molecular dispersing agents include polyvinylpyrrolidone, BYK Series (registered trademark, manufactured by BYK-Chemie GmbH), SOLSPERSE Series (registered trademark, manufactured by Lubrizol Japan Limited, etc.), AJISPER Series (registered trademark, manufactured by Ajinomoto Co., Inc.), and the like.

In a case in which a high-molecular dispersing agent other than the dispersing agent used for producing the metal nanowires is further separately added as a dispersing agent, it should be considered that the high-molecular dispersing agent is also encompassed by the binder as the component (c) and the content thereof is included in the content of the above-mentioned component (c).

The content of the dispersing agent in the conductive layer is preferably from 0.1 part by mass to 50 parts by mass, more preferably from 0.5 part by mass to 40 parts by mass, and particularly preferably from 1 part by mass to 30 parts by mass, based on 100 parts by mass of the binder as the component (c).

The content of the dispersing agent of 0.1 part by mass or more is preferable since the agglomeration of the metal nanowires in a dispersion is effectively suppressed, while the content of 50 parts by mass or less is preferable since a stable liquid film is formed to suppress occurrence of coating unevenness in a coating step.

(d-4) Solvent

The solvent is a component used to prepare a composition containing the above-mentioned metal nanowires, the specific alkoxide compound, and the photopolymerizable composition as a coating liquid for applying the composition in a film shape on a base material surface. It can be appropriately selected depending on a purpose, and examples include propylene glycol monomethyl ether, propylene glycol monomethyl ether acetate, ethyl 3-ethoxypropanoate, methyl 3-methoxypropionate, ethyl lactate, 3-methoxybutanol, water, 1-methoxy-2-propanol, isopropyl acetate, methyl lactate, N-methylpyrrolidone (NMP), γ-butyrolactone (GBL), propylene carbonate, and the like. As this solvent, at least one part of the solvent for the dispersion of the above-mentioned metal nanowires may serve. They may be used alone or in combination of two or more kinds. A solid content of the coating liquid containing such a solvent is preferably in a range of from 0.1 mass % to 20 mass %.

(d-5) Metal Corrosion Inhibitor

The conductive layer preferably contains a metal corrosion inhibitor for the metal nanowires. Such a metal corrosion inhibitor is not particularly limited and can be appropriately selected depending on a purpose, and preferable examples include thiols, azoles, and the like.

The inclusion of the metal corrosion inhibitor enables an antirust effect to be exerted and the deterioration in the electrical conductivity and the transparency of the conductive member with time to be suppressed. The metal corrosion inhibitor can be applied into a composition for forming a conductive layer by adding the metal corrosion inhibitor in the state of being dissolved in a suitable solvent or in state of being a powder or by soaking a conductive film into a metal corrosion inhibitor bath after producing the conductive film by using a coating liquid for a conductive layer described below. In the case of adding the metal corrosion inhibitor, the content thereof in the conductive layer is preferably from 0.5 mass % to 10 mass % based on the content of the metal nanowires.

As the additional matrix, the high-molecular compound as the dispersing agent used in the case of producing the above-mentioned metal nanowires can be used as at least one part of a component for forming the matrix.

In addition to the metal nanowires, another conductive material such as electrically-conductive fine particles can be used together in the conductive layer as long as the effect of the present invention is not impaired. From the viewpoint of the effect, the content ratio of the metal nanowires (preferably the metal nanowires with an aspect ratio of 10 or more) is preferably 50% or more, more preferably 60% or more, and particularly preferably 75% or more, on a volume basis, based on the total amount of the conductive material including the metal nanowires. The content ratio of the metal nanowires of 50% enables an intense network of the metal nanowires to be formed and the conductive layer having high electrical conductivity to be easily obtained.

Conductive particles with shapes other than those of the metal nanowires may not greatly contribute to the electrical conductivity of the conductive layer but may have absorption in the visible light region. In particular, in a case in which the conductive particles are metals and have shapes with high plasmon absorption, such as a spherical shape, the transparency of the conductive layer may be deteriorated.

The ratio of the metal nanowires can be determined as described below. For example, in a case in which the metal nanowires are silver nanowires and the conductive particles are silver particles, an aqueous dispersion of the silver nanowires is filtrated to separate the silver nanowires from the other conductive particles, the amount of silver remaining on filter paper and the amount of silver passed through the filter paper are each measured using an inductively coupled plasma (ICP) emission spectrometry apparatus, and the ratio of the metal nanowires can be calculated. The aspect ratio of the metal nanowires is calculated by observing metal nanowires remaining on the filter paper with TEM to measure the minor axis length and major axis length of each of 300 metal nanowires therein.

A method of measuring the average minor axis length and average major axis length of the metal nanowires is as described above.

A method of forming the conductive layer on the base material is not particularly limited, and the formation can be carried out by a common coating method, which can be appropriately selected depending on a purpose. Examples include a roll coating method, a bar coating method, a dip coating method, a spin coating method, a casting method, a die coating method, a blade coating method, a gravure coating method, a curtain coating method, a spray coating method, a doctor coating method, and the like.

<<Intermediate Layer>>

The conductive member preferably has at least one intermediate layer disposed between the base material and the conductive layer. At least one of adhesiveness between the base material and the conductive layer, the total light transmittance of the conductive layer, the haze of the conductive layer, and the film strength of the conductive layer can be improved by disposing the intermediate layer between the base material and the conductive layer.

Examples of the intermediate layer include an adhesive layer for improving adhesive strength between the base material and the conductive layer, a functional layer that improves functionality by interaction with a component contained in the conductive layer, and the like, and such an intermediate layer can be appropriately disposed depending on a purpose.

The configuration of the conductive member that further has the intermediate layer is explained with reference to the drawings.

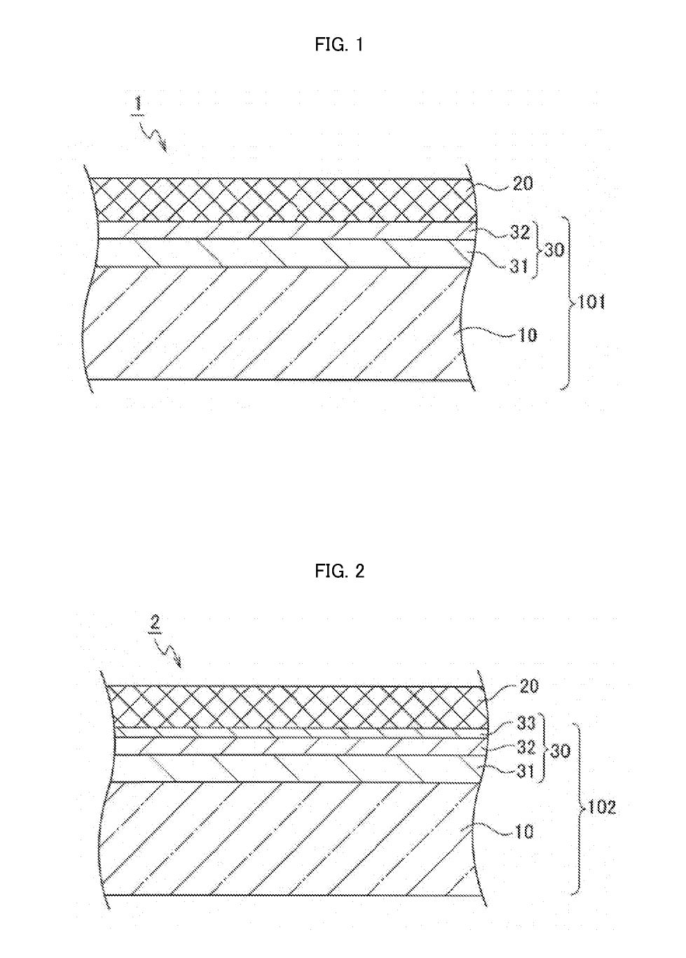

FIG. 1 is a schematic cross-sectional view that illustrates a conductive member 1 which is a first exemplary embodiment of a conductive member according to a first embodiment. In the conductive member 1, a conductive layer 20 is disposed on a substrate 101 including an intermediate layer on a base material. The intermediate layer 30 including a first adhesive layer 31 having an excellent affinity for the base material 10 and a second adhesive layer 32 having an excellent affinity for the conductive layer 20 is provided between the base material 10 and the conductive layer 20.

FIG. 2 is a schematic cross-sectional view that illustrates a conductive member 2 which is a second exemplary embodiment of the conductive member according to the first embodiment. An intermediate layer 30 including a functional layer 33 adjacent to a conductive layer 20 as well as a first adhesive layer 31 and a second adhesive layer 32 which are similar to those of the first embodiment is provided between a base material 10 and the conductive layer 20.

A material used for the intermediate layer 30 is not particularly limited and may be any one as long as it improves at least one of the above-described characteristics.

For example, in a case in which an adhesive layer is included as the intermediate layer, the adhesive layer contains a material selected from, e.g., polymers used in adhesives, silane coupling agents, titanium coupling agents, and sol gel films obtained by hydrolyzing and polycondensing an alkoxide compound of Si.

It is preferable that the intermediate layer which contacts the conductive layer (, which is either the intermediate layer itself in a case in which the intermediate layer 30 is a single layer or a subintermediate layer which is one of plural subintermediate layers and contacts the conductive layer in a case in which the intermediate layer 30 has the plural subintermediate layers,) is a functional layer 33 containing a compound having a functional group that can electrostatically mutually interact with metal nanowires contained in the conductive layer 20 (hereinafter referred to as a “functional group which can mutually interact with metal nanowires”) since the conductive layer excellent in total light transmittance, haze, and film strength is obtained. In the case of having such an intermediate layer, the conductive layer having excellent film strength is obtained even if the conductive layer 20 contains metal nanowires and an organic polymer.

This action is not clear but it is considered that the agglomeration of the conductive material in the conductive layer is suppressed, homogeneous dispersibility is improved, deterioration in transparency or haze caused by agglomeration of the conductive material in the conductive layer is suppressed, and improvement in film strength is achieved due to adhesiveness by interaction between the metal nanowires contained in the conductive layer and the compound having the above-described functional group contained in the intermediate layer by disposing the intermediate layer containing the compound having the functional group which can mutually interact with the metal nanowires contained in the conductive layer 20. Hereinafter, the intermediate layer that can express such interaction properties may be referred to as a functional layer. The functional layer exerts the effect thereof by the interaction with the metal nanowires and therefore expresses the effect without depending on a matrix contained in the conductive layer as long as the conductive layer contains the metal nanowires.

Examples of the functional group that can mutually interact with the metal nanowires include an amide group, an amino group, a mercapto group, a carboxylic acid group, a sulfonic acid group, a phosphate group, a phosphonic acid group, or salts thereof in a case in which the metal nanowires are silver nanowires, and the compound more preferably has one or plural functional groups selected from the group consisting of them. The functional group is more preferably an amino group, a mercapto group, a phosphate group, a phosphonic acid group, or salts thereof, further preferably an amino group.

Examples of compounds having a functional group as described above include compounds having an amide group, such as ureidopropyl triethoxy silane, polyacrylamide, and polymethacrylamide; compounds having an amino group, such as N-β(aminoethyl)γ-aminopropyl trimethoxy silane, 3-aminopropyl triethoxy silane, bis(hexamethylene)triamine, N,N′-bis(3-aminopropyl)-1,4-butanediamine tetrahydrochloride, spermine, diethylenetriamine, m-xylenediamine, and methaphenilene diamine; compounds having a mercapto group, such as 3-mercaptopropyl trimethoxy silane, 2-mercaptobenzothiazole, and toluene-3,4-dithiol; compounds having a group of sulfonic acid or a salt thereof, such as poly(p-sodium styrenesulfonate) and poly(2-acrylamide-2-methylpropanesulfonic acid); compounds having a carboxylic acid group, such as polyacrylic acid, polymethacrylic acid, polyaspartic acid, terephthalic acid, cinnamic acid, fumaric acid, and succinic acid; compounds having a phosphate group, such as PHOSMER PE, PHOSMER CL, PHOSMER M, and PHOSMER MH (trade names, manufactured by Uni-Chemical Co., Ltd.) and polymers thereof, POLYPHOSMER M-101, POLYPHOSMER PE-201, and POLYPHOSMER MH-301 (trade names, manufactured by DAP Co., Ltd.); and compounds having a phosphonic acid group, such as phenyl phosphonic acid, decyl phosphonic acid, methylene diphosphonic acid, vinyl phosphonic acid, and allylphosphonic acid.

By selecting these functional groups, agglomeration of the metal nanowires, which may occur due to the interaction between the metal nanowires and the functional group contained in the intermediate layer during drying after coating a coating liquid for forming a conductive layer, can be suppressed, and the conductive layer in which the metal nanowires are homogeneously dispersed may be formed.

The intermediate layer can be formed by: coating the base material with a liquid, in which a compound that forms the intermediate layer is dissolved, dispersed, or emulsified; and drying the liquid. A common method can be used as a coating method therefor. The method is not particularly limited and can be appropriately selected depending on a purpose, and examples include a roll coating method, a bar coating method, a dip coating method, a spin coating method, a casting method, a die coating method, a blade coating method, a gravure coating method, a curtain coating method, a spray coating method, a doctor coating method, and the like.

The conductive member has excellent wearing resistance. The wearing resistance can be evaluated by, e.g., the following method (1) or (2).

(1) In a case in which an wearing resistance test is conducted in which gauze (e.g., FC GAUZE (trade name, manufactured by Hakujuji Co., Ltd.)) is pressed on a surface of the conductive layer at a pressure of 125 g/cm² to rub the surface to and fro with the gauze 50 times using a continuous loading scratching tester (e.g., continuous loading scratching tester, trade name: TYPE18S, manufactured by Shinto Scientific Co., Ltd.), a ratio of the surface resistivity (Ω/sq.) of the conductive layer after the wearing resistance test/the surface resistivity (Ω/sq.) of the conductive layer before the wearing resistance test is 100 or less, more preferably 50 or less, and further preferably 10 or less.

(2) In a case in which the conductive member is subjected to a 20-time bending test using a cylindrical mandrel bending tester including a cylindrical mandrel having a diameter of 10 mm (e.g., manufactured by COTEC CORPORATION), a ratio of the surface resistivity (Ω/sq.) of the conductive layer after the test to the surface resistivity (Ω/sq.) of the conductive layer before the test is 5.0 or less, more preferably 2.5 or less, and further preferably 2.0 or less.

<Shape of Conductive Layer>

The shape of the conductive layer in the conductive member in the case of being observed from a direction perpendicular to a base material surface is not particularly limited and can be appropriately selected depending on a purpose. The conductive layer may include a non-conductive region. In other words, the conductive layer may be any of a first embodiment in which the whole region of the conductive layer is a conductive region (hereinafter, this conductive layer is also referred to as “non-patterned conductive layer”) or a second embodiment in which the conductive layer includes a conductive region and a non-conductive region (hereinafter, this conductive layer is also referred to as “patterned conductive layer”). In the case of the second embodiment, the non-conductive region may or may not include metal nanowires. In a case in which the non-conductive region includes metal nanowires, the metal nanowires included in the non-conductive region are disconnected.

The conductive member according to the first embodiment can be used as, e.g., a transparent electrode for a solar cell.

The conductive member according to the second embodiment can be used, e.g., in the case of producing a touch panel. In this case, the conductive and non-conductive regions having desired shapes are formed.

[Conductive Layer Including Conductive Region and Non-Conductive Region (Patterned Conductive Layer)]

The patterned conductive layer is produced by, e.g., the following patterning methods.

(1) A patterning method including: forming a non-patterned conductive layer in advance; and irradiating metal nanowires contained in a desired region of the non-patterned conductive layer with a high-energy laser beam such as carbon dioxide gas laser or a YAG laser to disconnect or vanish a part of the metal nanowires to make the desired region as a non-conductive region. This method is described in, e.g., Japanese Patent Application Laid-Open (JP-A) No. 2010-44968.

(2) A patterning method including: placing a photosensitive composition (photoresist) layer capable of forming a resist layer on a non-patterned conductive layer formed in advance; subjecting the photosensitive composition layer to desired pattern exposure and development to form a resist with the pattern shape; and thereafter etching and removing metal nanowires in a conductive layer in a region that is not protected by the resist, by a wet process of treatment with an etching liquid capable of etching metal nanowires or a dry process such as reactive ion etching. This method is described in, e.g., Japanese National Phase Publication (JP-A) No. 2010-507199 (particularly, paragraphs 0212 to 0217).

(3) A patterning method including: applying an etching liquid in which metal nanowires can be dissolved in a desired pattern shape on a non-patterned conductive layer formed in advance; and etching and removing metal nanowires in a conductive layer in a region to which the etching liquid is applied.

A light source used for the pattern exposure is selected in relation to the exposure wavelength region of a photoresist composition and, in general, ultraviolet rays such as g-ray, h-ray, i-ray, and j-ray are preferably used. A blue LED may also be used.

A pattern exposure method is not also particularly limited and may be performed by plane exposure using a photomask or may be performed by scanning exposure with a laser beam or the like. In this case, refraction-type exposure using a lens or reflection-type exposure using a reflecting mirror may also be performed, and exposure systems such as contact exposure, proximity exposure, reduced size projection exposure, and reflection projection exposure can be used.

The etching liquid in which the metal nanowires can be dissolved can be appropriately selected depending on the kind of the metal nanowires. In a case in which the metal nanowires are silver nanowires, examples include bleaching-fixing liquid, strong acid, oxidizing agent, hydrogen peroxide, and the like, which are generally used in the step of bleaching and fixing photographic paper with a silver halide color photosensitive material in a so-called photographic science field. Of these, bleaching-fixing liquid, dilute nitric acid, and hydrogen peroxide are particularly preferable. In the dissolution of the metal nanowires with the etching liquid, the metal nanowires in the portion to which the etching liquid is applied may not be necessarily completely dissolved and a part thereof may be allowed to remain as long as electrical conductivity vanishes.

The concentration of the dilute nitric acid is preferably from 1 mass % to 20 mass %.

The concentration of the hydrogen peroxide is preferably from 3 mass % to 30 mass %.

As the bleaching-fixing liquid, for example, treatment materials and treatment methods described in page 26, lower-right column, line 1 to page 34, upper-right column, line 9 in Japanese Patent Application Laid-Open (JP-A) No. H2-207250 and page 5, upper-left column, line 17 to page 18, lower-right column, line 20 in Japanese Patent Application Laid-Open (JP-A) No. H4-97355 are preferably applicable.

Bleaching-fixing time is preferably 180 seconds or less, more preferably from 1 second to 120 seconds, and further preferably from 5 seconds to 90 seconds. Further, washing or stabilizing time is preferably 180 seconds or less, and more preferably from 1 second to 120 seconds.

The bleaching-fixing liquid is not particularly limited as long as the bleaching-fixing liquid is a bleaching-fixing liquid for photography and can be appropriately selected depending on a purpose, and examples include CP-48S and CP-49E (trade names, bleaching-fixing agent for color paper manufactured by FUJIFILM Corporation); EKTACOLOR RA (trade names, bleaching-fixing liquids manufactured by Kodak Japan Ltd.; bleaching fixing liquids D-J2P-02-P2, D-30P2R-01 and D-22P2R-01 (all trade names, manufactured by Dai Nippon Printing Co., Ltd.); and the like. Of these, CP-48S and CP-49E are particularly preferable.

The viscosity of the etching liquid in which the metal nanowires can be dissolved is preferably from 5 mPa·s to 300,000 mPa·s, and more preferably from 10 mPa·s to 150,000 mPa·s, at 25° C. The viscosity of at least 5 mPa·s enables control of the diffusion of the etching liquid in a desired range to be facilitated to secure patterning in which a boundary between the conductive region and the non-conductive region is clear, while the viscosity of 300,000 mPa·s or less enables printing of the etching liquid without burden to be secured and treatment time required for dissolving the metal nanowires to be completed in desired time.

The method of forming the non-conductive region by applying the etching liquid is not particularly limited as long as it is a method of applying the etching liquid in a pattern form on the conductive layer, and can be appropriately selected depending on a purpose. Examples include: screen printing; ink-jet printing; a method of forming an etching mask with a resist agent or the like in advance and subjecting an etching liquid to coater coating, roller coating, dipping coating, or spray coating thereon; and the like. Of these, screen printing, ink-jet printing, coater coating, and dip (dipping) coating are particularly preferable.

As the ink-jet printing, for example, both piezo system and thermal system can be used.

The kind of the pattern is not particularly limited and can be appropriately selected depending on a purpose, and examples include characters, signs, designs, figures, wiring patterns, and the like.

The size of the pattern is not particularly limited and can be appropriately selected depending on a purpose and may be any size of from a nanometer order size to a millimeter order size.

The conductive member preferably has a surface resistivity of 1,000 Ω/sq. or less. In the case of the conductive member having a non-patterned conductive layer, the above-described surface resistivity is the surface resistivity of the conductive layer, while in the case of the conductive member having a patterned conductive layer, the above-described surface resistivity is the surface resistivity of the conductive layer in a conductive region.

The above-described surface resistivity is a value obtained by measuring the surface, in a side opposite to a base material side, of the conductive layer in the conductive member by a four-point probe method. As a method of measuring the surface resistivity by the four-point probe method, the measurement can be carried out in conformity with, e.g., JIS K 7194: 1994 (Testing method of resistivity of conductive plastics with a four-point probe array) or the like and the measurement can be easily carried out using a commercially available surface resistivity meter. In order to achieve a surface resistivity of 1,000 Ω/sq. or less, at least one of the kind of metal nanowires contained in the conductive layer and the content ratio between the specific alkoxide compound and the metal nanowires may be adjusted. More specifically, the conductive layer having a surface resistivity in a desired range can be formed by adjusting the mass ratio between the contents of the specific alkoxide compound and the metal nanowires in a range of from 0.25/1 to 30/1.

The surface resistivity of the conductive member is further preferably in a range of from 0.1 Ω/sq. to 900 Ω/sq.

The conductive member is widely applied to, e.g., touch panels, electrodes for displays, electromagnetic wave shields, electrodes for organic EL displays, electrodes for inorganic EL displays, electronic papers, electrodes for flexible displays, integrated solar cells, liquid crystal display apparatuses, display apparatuses with touch panel functions, other various devices, and the like since the conductive layer has high electrical conductivity, transparency and high film strength and is excellent in wearing resistance and flexibility. Of these, the applications to touch panels and solar cells are particularly preferable.

<<Touch Panel>>

The conductive member is applied to, e.g., surface type capacitive sensing system touch panels, projection type capacitive sensing system touch panels, resistor film type touch panels, and the like. Such touch panels include so-called touch sensors and touch pads.

The layer configuration of a touch panel sensor electrode section in such a touch panel as described above is preferably any of a lamination system in which two transparent electrodes are laminated, a system in which transparent electrodes are disposed on both surfaces of one base material, a single surface jumper or through-hole system, or a single surface stacking system.

Such a surface type capacitive sensing system touch panel as described above is described in, e.g., Japanese National Phase Publication (JP-A) No. 2007-533044.

<<Solar Cell>>

The conductive member is useful as a transparent electrode in an integrated solar cell (hereinafter also referred to as a solar cell device).

The integrated solar cell is not particularly limited and an integrated solar cell that is generally used as the solar cell device can be used. Examples include monocrystalline silicon solar cell devices, polycrystalline silicon solar cell devices, amorphous silicon solar cell devices configured by a single junction type, a tandem structure type, or the like, III-V compound semiconductor solar cell devices of gallium arsenide (GaAs), indium phosphide (InP), or the like, II-VI compound semiconductor solar cell devices of cadmium telluride (CdTe) or the like, copper/indium/selenium (so-called CIS), copper/indium/gallium/selenium (so-called CIGS), or copper/indium/gallium/selenium/sulfur (so-called CIGSS) I-III-VI compound semiconductor solar cell devices, dye-sensitized solar cell devices, organic solar cell devices, and the like. Of these, the solar cell devices are preferably amorphous silicon solar cell devices constituted by a tandem structure type or the like and copper/indium/selenium (so-called CIS), copper/indium/gallium/selenium (so-called CIGS), or copper/indium/gallium/selenium/sulfur (so-called CIGSS) I-III-VI group compound semiconductor solar cell devices.

In the case of the amorphous silicon solar cell devices configured by a tandem structure type or the like, amorphous silicon and microcrystalline silicon thin layers, thin films in which they contain Ge, and tandem structures with two or more layers thereof are used as photoelectric conversion layers. A plasma chemical vapor deposition method (CVD) or the like is used for forming the layers.

The conductive member is applicable for all the solar cell devices. Although the conductive member may be included in any portion of a solar cell device, the conductive layer is preferably disposed to be adjacent to a photoelectric conversion layer. As for a positional relationship with respect to the photoelectric conversion layer, configurations described below are preferable without limitation thereto. Further, the configurations described below do not describe all portions which form a solar cell device but describe to the extent that the positional relationship of the transparent conductive layer is recognized. Bracketed components correspond to the conductive member.

(A) [Base material-conductive layer]-photoelectric conversion layer
(B) [Base material-conductive layer]-photoelectric conversion layer-[conductive layer-base material]
(C) Substrate-electrode-photoelectric conversion layer-[conductive layer-base material]
(D) Back surface electrode-photoelectric conversion layer-[conductive layer-base material]

Details of such solar cells are described in, e.g., Japanese Patent Application Laid-Open (JP-A) No. 2010-87105.

### EXAMPLES

Examples of the present invention are explained below, but the present invention is not limited to the examples at all. Both “%” and “part(s)” as contents in the examples are based on mass.

In the examples below, the average minor axis length (average diameter) and average major axis length of metal nanowires, a coefficient of variation of the minor axis length, and a ratio of silver nanowires having an aspect ratio of 10 or more with respect to all the metal nanowires were measured in such a manner below.

<Average Minor Axis Length (Average Diameter) and Average Major Axis Length of Metal Nanowires>

The minor axis lengths (diameters) and major axis lengths of 300 metal nanowires randomly selected from metal nanowires observed under magnification using a transmission electron microscope (TEM, trade name: JEM-2000FX manufactured by JEOL Ltd.) were measured, and the average minor axis length (average diameter) and average major axis length of the metal nanowires were determined from the average values thereof.

### <Coefficient of Variation of Minor Axis Length (Diameter) of Metal Nanowire>

It was determined by measuring the minor axis lengths (diameters) of 300 nanowires randomly selected from the above-described electron microscope (TEM) image and calculating the standard deviation and average value of the 300 nanowires.

<Ratio of Silver Nanowires with Aspect Ratio of 10 or More>

The minor axis lengths of 300 silver nanowires were observed using the transmission electron microscope (JEM-2000FX: mentioned above), the amount silver passed through filter paper was each measured, and a ratio of the number of silver nanowires having a minor axis length of 50 nm or less and a major axis length of 5 μm or more to the 300 silver nanowires were determined as the ratio (%) of the silver nanowires having an aspect ratio of 10 or more.

In addition, the separation of the silver nanowires for determining the ratio of the silver nanowires was carried out using a membrane filter (manufactured by EMD Millipore Corporation, trade name: FALP 02500, bore diameter: 1.0 μm).

### Preparation Example 1

### —Preparation of Silver Nanowire Aqueous Dispersion (1)—

Liquid additives A, G, and H described below were prepared in advance.

### [Liquid Additive A]

In 50 mL of pure water, 0.51 g of silver nitrate powder was dissolved. Then, 1 N ammonia water was added until the resultant became transparent. Pure water was further added so that the total amount was 100 mL.

### [Liquid Additive G]

In 140 mL of pure water, 0.5 g of glucose powder was dissolved to prepare a liquid additive G.

### [Liquid Additive H]

In 27.5 mL of pure water, 0.5 g of HTAB (hexadecyl-trimethylammoniumbromide) powder was dissolved to prepare a liquid additive H.

Then, a silver nanowire aqueous dispersion (1) was prepared in a manner below.

In a three-necked flask, 410 mL of pure water was put and 82.5 mL of the liquid additive H and 206 mL of the liquid additive G were added through a funnel while stirring at 20° C. (first stage). To this liquid, 206 mL of the liquid additive A was added at a flow rate of 2.0 mL/min and a stirring rotation number of 800 rpm (second stage). Ten minutes later, 82.5 mL of the liquid additive H was added (third stage). Then, inner temperature was increased to 73° C. at 3° C./min. Then, a stirring rotation number was decreased to 200 rpm and heating was carried out for 5.5 hours.

After cooling the resultant aqueous dispersion, an ultrafiltration module SIP1013 (trade name, manufactured by Asahi Kasei Corp., molecular cutoff: 6,000), a magnet pump, and a stainless steel cup were connected through tubes made of silicone to make an ultrafiltration apparatus.

The silver nanowire dispersion (aqueous solution) was poured into the stainless steel cup and the pump was operated to perform ultrafiltration. When a filtrate from the module became 50 mL, 950 mL of distilled water was added to the stainless steel cup to perform washing. The washing was repeated until conductivity became 50 μS/cm or less, followed by concentrating to obtain a 0.84% silver nanowire aqueous dispersion.

An average minor axis length, an average major axis length, a ratio of silver nanowires having an aspect ratio of 10 or more, and the coefficient of variation of the minor axis lengths of the silver nanowires in the resultant Preparation Example 1 were measured as described above.

As a result, the silver nanowires having an average minor axis length of 17.2 nm, an average major axis length of 34.2 μm, and a coefficient of variation of 17.8% were obtained. The ratio of the silver nanowires having an aspect ratio of 10 or more in the resultant silver nanowires was 81.8%. Hereinafter, the expression “silver nanowire aqueous dispersion (1)” represents the aqueous dispersion of silver nanowire obtained by the above-described method.

### Preparation Example 2

### —Pretreatment of Glass Substrate—

First, an alkali-free glass plate with a thickness of 0.7 mm dipped in a 1% aqueous solution of sodium hydroxide was subjected to ultrasonic irradiation for 30 minutes by an ultrasonic wave washer, then washed with ion-exchanged water for 60 seconds, and thereafter subjected to heat treatment at 200° C. for 60 minutes. Then, a 0.3% aqueous solution of KBM-603 (trade name, N-(β-aminoethyl)-γ-aminopropyl trimethoxy silane, manufactured by Shin-Etsu Chemical Co., Ltd.) as a silane coupling liquid was sprayed for 20 seconds by a shower to perform pure water shower washing. Hereinafter, the expression “glass substrate” represents an alkali-free glass substrate obtained by the above-described pretreatment.

### Preparation Example 3

### —Production of PET Substrate 101 Having Configuration Represented in FIG. 1—

A solution 1 for adhesion was prepared in the following formulation.

### [Solution 1 for Adhesion]

| | |
|---|---|
| TAKELAC (registered trademark) WS-4000 | 5.0 parts |
| (polyurethane for coating, solid content: 30%, manufactured | |
| by Mitsui Chemicals, Inc.) | |
| Surfactant | 0.3 part |
| (trade name: NAROACTY HN-100, manufactured by Sanyo | |
| Chemical Industries, Ltd.) | |
| Surfactant | 0.3 part |
| (SANDET (registered trademark) BL, solid content: 43%, | |
| manufactured by Sanyo Chemical Industries, Ltd.) | |
| Water | 94.4 parts |

One surface of a PET film 10 having a thickness of 125 μm was subjected to corona discharge treatment and the surface subjected to the corona discharge treatment was coated with the solution 1 for adhesion and dried at 120° C. for 2 minutes to form a first adhesive layer 31 having a thickness of 0.11 μm.

A solution 2 for adhesion was prepared in the formulation.

### [Solution 2 for Adhesion]

| | |
|---|---|
| Tetraethoxy silane | 5.0 parts |
| (trade name: KBE-04, manufactured by Shin-Etsu Chemical | |
| Co., Ltd.) | |
| 3-Glycidoxypropyl trimethoxy silane | 3.2 parts |
| (trade name: KBM-403, manufactured by Shin-Etsu | |
| Chemical Co., Ltd.) | |
| 2-(3,4-Epoxycyclohexyl)ethyl trimethoxy silane | 1.8 parts |
| (trade name: KBM-303, manufactured by Shin-Etsu | |
| Chemical Co., Ltd.) | |
| Aqueous acetic acid solution (acetic acid concentration = | 10.0 parts |
| 0.05%, PH = 5.2) | |
| Curing agent | 0.8 part |
| (boric acid, manufactured by Wako Pure Chemical | |
| Industries, Ltd.) | |
| Colloidal silica | 60.0 parts |
| (SNOWTEX (registered trademark) O, average particle | |
| diameter: 10 nm to 20 nm, solid content: 20%, pH = 2.6, | |
| manufactured by Nissan Chemical Industries, Ltd.) | |
| Surfactant | 0.2 part |
| (NAROACTY HN-100 (mentioned above)) | |
| Surfactant | 0.2 part |
| (SANDET (registered trademark) BL, solid content: 43%, | |
| manufactured by Sanyo Chemical Industries, Ltd.) | |

The solution 2 for adhesion was prepared by a method below. While vigorously stirring an aqueous acetic acid solution, 3-glycidoxypropyl trimethoxy silane was dropwise added into the aqueous acetic acid solution for 3 minutes. Then, 2-(3,4-epoxycyclohexyl)ethyl trimethoxy silane was added into the aqueous acetic acid solution for 3 minutes while vigorously stirring. Then, tetraethoxy silane was added into the aqueous acetic acid solution for 5 minutes while vigorously stirring and the stirring was thereafter continued for 2 hours. Then, the colloidal silica, the curing agent, and the surfactants were sequentially added to prepare the solution 2 for adhesion.

A surface of the first adhesive layer 31 was subjected to corona discharge treatment, the surface was thereafter coated with the solution 2 for adhesion by a bar coating method, heated at 170° C. for 1 minute, and dried, to form a second adhesive layer 32 having a thickness of 0.5 μm. A PET substrate 101 having the configuration shown in FIG. 1 was thus obtained.

(Production of Conductive Member 1)

A solution of an alkoxide compound having a composition described below was stirred at 60° C. for 1 hour and was confirmed to be homogeneous. Mixing of 3.65 parts of the resultant sol-gel solution with 16.35 parts of the silver nanowire aqueous dispersion (1) obtained in Preparation Example 1 was carried out and the mixture was further diluted with distilled water to obtain a sol-gel coating liquid. A surface of the second adhesive layer 32 of the PET substrate 101 was subjected to corona discharge treatment, coated with the sol-gel coating liquid by a bar coating method so that the amount of silver was 0.015 g/m² and the total amount of a coated solid was 0.128 g/m², and then dried at 175° C. for 1 minute to cause a sol-gel reaction, to form a conductive layer 20. Thus, the non-patterned conductive member 1 having the configuration represented in the cross-sectional view of FIG. 1 was obtained. A mass ratio of [tetraethoxysilane (alkoxide compound)]/[silver nanowires] in the conductive layer was 7/1.

### <Solution of Alkoxide Compound>

| | |
|---|---|
| Tetraethoxysilane | 5.0 parts |
| (KBE-04 (mentioned above)) | |
| 1% aqueous acetic acid solution | 10.0 parts |
| Distilled water | 4.0 parts |

An average film thickness of the conductive layer measured using a probe-type surface shape measuring device (DEKTAK (registered trademark) 150, manufactured by Bruker AXS) was 0.065 μm.

An average film thickness of the conductive layer measured using an electron microscope as described below was 0.029 μm.

### (Method of Measuring Thickness Using Electron Microscope)

A protective layer of carbon and Pt was formed on the conductive member. A slice of about 10 μm in width and about 100 nm in thickness was then produced from the conductive member in a convergence ion beam apparatus (trade name: FB-2100) manufactured by Hitachi, Ltd. The cross section of the conductive layer was observed with a scanning transmission electron microscope (trade name: HD-2300, manufactured by Hitachi, Ltd., applied voltage: 200 kV). The film thicknesses of five points of the conductive layer were measured, and an average film thickness was calculated as the arithmetic mean value thereof. The average film thickness was calculated by measuring the thicknesses of only matrix components in which any metal wire does not exist.

It is remarked that only the measurement of the average film thickness was performed by subjecting the conductive member having the protective layer thereto, while measurements for evaluating other properties were performed by subjecting the conductive member on which the protective layer was not formed thereto.

A water drop contact angle of the surface of the conductive layer, measured at 25° C. using DM-701 (mentioned above), was 10°.

<<Patterning>>

The non-patterned conductive member 1 obtained as described above was subjected to a patterning treatment as follows. WHT-3 and SQUEEGEE No. 4 YELLOW (both trade names) manufactured by MINO GROUP CO., LTD. were used for screen printing. A solution of silver nanowires for forming a pattern was formed as ink for screen printing by mixing CP-48S-A LIQUID, CP-48S-B LIQUID (each trade name, manufactured by FUJIFILM Corporation), and pure water to be at 1:1:1 and thickening the mixture with hydroxyethyl cellulose. A pattern mesh used was a stripe pattern (line/space=50 μm/50 μm).

An etching liquid was applied to a partial region, on which a non-conductive region was formed, so that an application amount was 0.01 g/cm², and was then left to stand at 25° C. for 2 minutes. Then, patterning treatment was performed by washing with water. A conductive member 1 including a conductive layer having a conductive region and the non-conductive region was thus obtained.

A patterned conductive member 1 including the conductive layer having the conductive region and the non-conductive region was thus obtained by the above-described patterning treatment.

(Production of Conductive Members 2 to 13)

Conductive members 2 to 13 were obtained in the same manner as the production of the conductive member 1 except that each amount of the sol-gel solution and the silver nanowire aqueous dispersion (1) that were mixed in the preparation of the sol-gel coating liquid, the amount of silver coated on the PET substrate 101, and the total amount of the coated solid in the production of the conductive member 1 were changed as listed in Table 1 described below. In addition, thicknesses shown in Table 1 are numerical values of average film thicknesses measured using an electron microscope.

TABLE 1

| | Conductive layer | | | | | |
|---|---|---|---|---|---|---|
| | | Amount of mixed | | | Total | |
| | | aqueous dispersion of | Mass ratio of | Amount of | amount of | |
| Conductive | Amount of mixed | silver nanowire | Compound | silver | coated solid | Thickness |
| member | sol-gel liquid (part(s)) | (part(s)) | (II)/Conductive fibers | (g/m²) | (g/m²) | (μm) |
| 1 | 3.65 | 16.35 | 7/1 | 0.015 | 0.120 | 0.029 |
| 2 | 0.16 | 19.84 | 0.25/1 | 0.015 | 0.019 | 0.002 |
| 3 | 0.31 | 19.69 | 0.5/1 | 0.015 | 0.023 | 0.003 |
| 4 | 0.62 | 19.38 | 1/1 | 0.015 | 0.030 | 0.005 |
| 5 | 0.91 | 19.09 | 1.5/1 | 0.015 | 0.038 | 0.007 |
| 6 | 1.20 | 18.80 | 2/1 | 0.015 | 0.045 | 0.009 |
| 7 | 2.26 | 17.74 | 4/1 | 0.015 | 0.075 | 0.017 |
| 8 | 4.07 | 15.93 | 8/1 | 0.015 | 0.135 | 0.033 |
| 9 | 4.84 | 15.16 | 10/1 | 0.015 | 0.165 | 0.041 |
| 10 | 6.48 | 13.52 | 15/1 | 0.015 | 0.240 | 0.061 |
| 11 | 7.30 | 12.70 | 18/1 | 0.015 | 0.285 | 0.073 |
| 12 | 7.79 | 12.21 | 20/1 | 0.015 | 0.315 | 0.081 |
| 13 | 9.78 | 10.22 | 30/1 | 0.015 | 0.465 | 0.120 |

(Production of Conductive Member C1)

A conductive member C1 was obtained in the same manner as the production of the conductive member 1 except that no sol-gel solution was added in the production thereof. The average film thickness of the conductive layer was 0.002 μm.

(Production of Conductive Member C2)

A conductive member C2 was obtained in the same manner as in Example 1 except that the sol-gel solution was changed to a solution A described below in the production thereof. The average film thickness of the conductive layer was 0.150 μm.

### <Solution A>

| | |
|---|---|
| Polyvinylpyrrolidone | 5.0 parts |
| Distilled water | 14.0 parts |

(Production of Conductive Member C3)

A conductive member C3 was obtained in the same manner as in the production of the conductive member 1 except that the sol-gel solution was changed to a solution B described below and that the conductive layer 20 was exposed to the i-ray (365 nm) from an ultra-high-pressure mercury lamp at an exposure value of 40 mJ/cm² under nitrogen atmosphere in the production thereof.

### <Solution B>

| | |
|---|---|
| Dipentaerythritol hexaacrylate | 5.0 parts |
| Photopolymerization initiator: | 0.4 part |
| 2,4-bis-(trichloromethyl)-6-[4-{N,N- | |
| bis(ethoxycarbonylmethyl)amino}-3-bromophenyl]-s-triazine | |
| Methyl ethyl ketone | 13.6 parts |

(Production of Conductive Members C4 to C12)

Conductive members C4 to C12 were obtained in the same manner as in the case of the conductive member C3 except that each amount of the solution B and the silver nanowire aqueous dispersion (1) that were mixed, the amount of silver coated on the PET substrate 101, and the total amount of a coated solid in the production of conductive member C3 were changed as listed in Table 2 described below. Thicknesses in Table 2 are numerical values of average film thicknesses measured using an electron microscope.

TABLE 2

| | Conductive layer | | | | | |
|---|---|---|---|---|---|---|
| | | Amount of mixed | | | | |
| | | silver nanowire | Mass ratio of | | | |
| | Amount of | aqueous | Dipentaerythritol | Amount of | Total amount | |
| Conductive | mixed solution B | dispersion | hexaacrylate/Silver | silver | of coated | Thickness |
| member | (part(s)) | (part(s)) | nanowires | (g/m²) | solid (g/m²) | (μm) |
| C3 | 0.06 | 19.94 | 7/1 | 0.015 | 0.120 | 0.075 |
| C4 | 0.06 | 19.94 | 0.1/1 | 0.015 | 0.016 | 0.002 |
| C5 | 0.16 | 19.84 | 0.25/1 | 0.015 | 0.019 | 0.004 |
| C6 | 0.31 | 19.69 | 0.5/1 | 0.015 | 0.023 | 0.007 |
| C7 | 0.62 | 19.38 | 1/1 | 0.015 | 0.030 | 0.012 |
| C8 | 1.20 | 18.80 | 2/1 | 0.015 | 0.045 | 0.022 |
| C9 | 2.26 | 17.74 | 4/1 | 0.015 | 0.075 | 0.043 |
| C10 | 4.84 | 15.16 | 10/1 | 0.015 | 0.165 | 0.106 |
| C11 | 6.48 | 13.52 | 15/1 | 0.015 | 0.240 | 0.159 |
| C12 | 7.79 | 12.21 | 20/1 | 0.015 | 0.315 | 0.211 |

<<Evaluation>>

The surface resistivity, optical characteristics (total light transmittance and haze), wearing resistance, heat resistance, resistance to moist heat, flexibility, and etching properties of each obtained conductive member were evaluated by a method described below and the results are listed in Table 3. In addition, a non-patterned conductive member was used for the evaluation.

<Surface Resistivity>

The surface resistivity of the conductive region of the conductive layer was measured by using LORESTA (registered trademark)-GPMCP-T600 manufactured by Mitsubishi Chemical Corporation. The surface resistivities of five points randomly selected in the central section of the conductive region of a sample of 10 cm×10 cm were measured and the average value thereof was regarded as the surface resistivity of the sample.

<Optical Characteristics (Total Light Transmittance)>

The total light transmittance (%) of a portion corresponding to the conductive region of the conductive member and the total light transmittance (%) of the PET substrate 101 prior to the formation of the conductive layer 20 were measured using HAZE-GARD PLUS (trade name) manufactured by BYK-Gardner GmbH and the conversion of the transmittance of the conductive layer was carried out from the ratio thereof. For a CIE luminosity function y under an illuminant C, measurement at a measurement angle of 0° was carried out, the total light transmittances of five places randomly selected in the central section of the conductive region of a sample of 10 cm×10 cm were measured to calculate transmittances, and the average value thereof was regarded as the transmittance of the sample.

<Optical Properties (Haze)>

The haze value of a portion corresponding to the conductive region of the conductive member was measured using HAZE-GARD PLUS (mentioned above). The haze values of five points randomly selected in the central section of the conductive region of a sample of 10 cm×10 cm were measured and the average value thereof was regarded as the haze value of the sample.

<Wearing Resistance>

A surface of the conductive layer was rubbed to and fro 50 times at a load of 500 g with a size of 20 mm×20 mm using FC GAUZE (mentioned above) (i.e., the gauze was pressed on the surface of the conductive layer at a pressure of 125 g/cm² to rub the surface to and fro with the gause 50 times) and the presence or absence of a flaw and a variation in surface resistivity before and after the rubbing (surface resistivity after wearing/surface resistivity before wearing) were observed. A continuous loading scratching tester TYPE18S (trade name) manufactured by Shinto Scientific Co., Ltd. was used for the wearing test while the surface resistivity was measured using LORESTA-GP MCP-T600 (mentioned above). A case in which there is no flaw and a variation in surface resistivity is lower (closer to 1) means that the wearing resistance is superior. In addition, “OL” in the table means that the surface resistance value is 1.0×10⁸ Ω/sq. or more and there is no electrical conductivity.

<Heat Resistance>

The resultant conductive member was heated at 150° C. for 60 minutes to observe a change in surface resistivity ([surface resistivity after heat resistance test]/[surface resistivity before heat resistance test], also referred to as “change in resistance”) and a change in haze value ([haze value after heat resistance test]−[haze value before heat resistance test], also referred to as “change in haze”) before and after the heating. The surface resistivity was measured using LORESTA-GPMCP-T600 (mentioned above) while the haze value was measured using HAZE-GARD PLUS (mentioned above). The smaller a change in surface resistivity and a change in haze value are (the closer the change in resistance is to 1 and the closer the change in haze is to zero), the better the heat resistance is.

<Resistance to Moist Heat>

The resultant conductive member was left to stand under an environment at 60° C. and 90 RH % for 240 hours to observe a change in surface resistivity ([surface resistivity after test for resistance to moist heat]/[surface resistivity before test for resistance to moist heat], also referred to as “change in resistance”) and a change in haze value ([haze value after test for resistance to moist heat]−[haze value before test for resistance to moist heat], also referred to as “change in haze” before and after being left to stand. The surface resistivity was measured using LORESTA-GPMCP-T600 (mentioned above) while the haze value was measured using HAZE-GARD PLUS (mentioned above). The smaller a change in surface resistivity and a change in haze value are (the closer the change in resistance is to 1 and the closer the change in haze is to zero), the better the resistance to moist heat is.

<Flexibility>

The conductive member was subjected to a 20-time bending test using a cylindrical mandrel bending tester including a cylindrical mandrel having a diameter of 10 mm (manufactured by COTEC CORPORATION) to observe the presence or absence of a crack and a change in resistance value ([surface resistance value after bending test]/[surface resistance value before bending test]) before and after the test. The presence or absence of a crack was measured by visual observation and using an optical microscope while the surface resistance value was measured using LORESTA-GPMCP-T600 (mentioned above). A case in which there is no crack and a change in surface resistance value is smaller (closer to 1) means that flexibility is superior.

<Etching Properties>

The resultant conductive member was dipped at 25° C. in a solution (etching liquid) in which CP-48S-A LIQUID, CP-48S-B LIQUID (each trade name, manufactured by FUJIFILM Corporation), and pure water used for the pattern formation were mixed to be at 1:1:1, was then washed with flowing water, and was dried. The surface resistance value was measured using LORESTA-GPMCP-T600 (mentioned above). The haze value was measured using HAZE-GARD PLUS (mentioned above).

A case in which the surface resistance value is higher and Δhaze (difference in haze before and after dipping) is greater after dipped in the etching liquid means that etching properties are superior. Thus, etching liquid dipping time until the surface resistance value becomes 1.0×10⁸ Ω/sq. or more and Δhaze becomes 0.4% or more is determined and ranked in accordance with the following criteria.

Rank 5: Very excellent level, at which etching liquid dipping time until the surface resistance value becomes 1.0×10⁸ Ω/sq. or more and Δhaze becomes 0.4% or more is less than 30 seconds;

Rank 4: Excellent level, at which the above-explained time is 30 seconds or more and less than 60 seconds;

Rank 3: Good level, at which the above-explained time is 60 seconds or more and less than 120 seconds;

Rank 2: Level having a practical problem, at which the above-explained time is 120 seconds or more and less than 180 seconds; and

Rank 1: Level having a practically great problem, at which the above-explained time is 180 seconds or more.

TABLE 3

| | Evaluation results | | | | | | | | | |
|---|---|---|---|---|---|---|---|---|---|---|
| | | | | Wearing | Heat | | Resistance to | | | |
| | | | | resistance | resistance | | moist heat | | | |
| | Surface | | | (change | Change | | Change | | | |
| | resistance | Total light | | in surface | in surface | Change | in surface | Change | | |
| Conductive | value | transmittance | Haze | resistance | resistance | in haze | resistance | in haze | | Etching |
| member | (Ω/sq.) | (%) | (%) | value) | value | value | value | value | Flexibility | properties |
| 1 | 105 | 92 | 1.11 | 1.10 | 1.39 | 0.20 | 1.21 | 0.21 | 2.05 | 5 |
| 2 | 90 | 94 | 0.98 | 49.8 | 4.01 | 0.48 | 3.74 | 0.44 | 3.42 | 5 |
| 3 | 92 | 93 | 0.98 | 45.8 | 3.56 | 0.41 | 3.12 | 0.40 | 3.01 | 5 |
| 4 | 91 | 93 | 1.00 | 27.4 | 2.91 | 0.35 | 2.75 | 0.38 | 2.58 | 5 |
| 5 | 91 | 92 | 1.01 | 17.6 | 2.48 | 0.36 | 2.16 | 0.34 | 2.15 | 5 |
| 6 | 90 | 92 | 1.02 | 11.3 | 2.22 | 0.35 | 1.99 | 0.30 | 2.14 | 5 |
| 7 | 95 | 92 | 1.05 | 6.11 | 1.13 | 0.31 | 1.81 | 0.25 | 2.09 | 5 |
| 8 | 102 | 92 | 1.10 | 1.09 | 1.23 | 0.27 | 1.48 | 0.18 | 2.08 | 5 |
| 9 | 116 | 92 | 1.10 | 1.07 | 1.17 | 0.20 | 1.22 | 0.16 | 2.10 | 5 |
| 10 | 132 | 92 | 1.15 | 1.04 | 1.13 | 0.19 | 1.16 | 0.14 | 2.16 | 4 |
| 11 | 210 | 92 | 1.21 | 1.03 | 1.03 | 0.16 | 1.10 | 0.10 | 2.89 | 4 |
| 12 | 290 | 92 | 1.33 | 1.04 | 1.06 | 0.11 | 1.08 | 0.04 | 3.24 | 4 |
| 13 | 620 | 92 | 1.38 | 1.01 | 1.05 | 0.08 | 1.02 | 0.05 | 4.39 | 3 |
| C1 | 92 | 94 | 0.97 | O.L. | 6.25 | 0.68 | 10.5 | 0.95 | 2.63 | 4 |
| C2 | 90 | 92 | 1.09 | 300 | 4.86 | 0.52 | 5.23 | 0.59 | 1.25 | 5 |
| C3 | 2800 | 92 | 1.22 | 12.8 | 2.38 | 0.30 | 2.15 | 0.32 | 1.64 | 5 |
| C4 | 92 | 92 | 0.99 | 520 | 5.16 | 0.69 | 5.03 | 0.64 | 4.25 | 5 |
| C5 | 90 | 92 | 1.02 | 281 | 4.99 | 0.60 | 4.96 | 0.62 | 3.20 | 5 |
| C6 | 100 | 92 | 1.06 | 264 | 3.85 | 0.56 | 3.90 | 0.59 | 2.45 | 5 |
| C7 | 250 | 92 | 1.08 | 189 | 3.26 | 0.45 | 3.46 | 0.44 | 1.90 | 5 |
| C8 | 500 | 92 | 1.12 | 57.9 | 2.89 | 0.33 | 2.36 | 0.41 | 1.36 | 5 |
| C9 | 1500 | 92 | 1.20 | 31.7 | 2.57 | 0.32 | 2.30 | 0.39 | 1.58 | 5 |
| C10 | 3000 | 92 | 1.26 | 8.18 | 1.93 | 0.29 | 1.93 | 0.31 | 2.07 | 3 |
| C11 | 3.5 · 10⁴ | 91 | 1.33 | 2.46 | 1.59 | 0.26 | 1.50 | 0.28 | 2.09 | 3 |
| C12 | 2.6 · 10⁶ | 91 | 1.45 | 1.38 | 1.20 | 0.25 | 1.28 | 0.22 | 3.12 | 3 |

Based on the results listed in Table 3, the conductive member according to one embodiment of the present invention can be considered to be excellent in electrical conductivity, transparency (total light transmittance and haze), wearing resistance, heat resistance, resistance to moist heat, and flexibility.

(Production of Conductive Member 14)

A solution of an alkoxide compound having a composition described below was stirred at 60° C. for 1 hour and was confirmed to be homogeneous. Mixing of 3.44 parts of the resultant sol-gel solution with 16.56 parts of the aqueous dispersion of silver nanowire obtained in Preparation Example 1 was carried out and the mixture was further diluted with distilled water to obtain a sol-gel coating liquid. A surface of the second adhesive layer 32 of the PET substrate 101 was subjected to corona discharge treatment, coated with the sol-gel coating liquid by a bar coating method so that the amount of silver was 0.020 g/m² and the total amount of a coated solid was 0.150 g/m², and then dried at 175° C. for 1 minute to cause a sol-gel reaction to form a conductive layer 20. Thus, a non-patterned conductive member 14 having the configuration represented in the cross-sectional view of FIG. 1 was obtained. A mass ratio of [tetraethoxysilane (alkoxide compound)]/[silver nanowires] in the conductive layer was 6.5/1.

Patterning treatment of the non-patterned conductive member 14 obtained as described above was performed in the same manner as in the case of the production of the conductive member 14 to obtain the conductive member 14.

### <Solution of Alkoxide Compound>

| | |
|---|---|
| Tetraethoxysilane (KBE-04 (mentioned above)) | 5.0 parts |
| 1% aqueous acetic acid solution | 10.0 parts |
| Distilled water | 4.0 parts |

### (Production of Conductive Members 15 to 23)

Conductive members 15 to 23 were obtained in the same manner as in the production of the conductive member 14 except that tetraalkoxy and organoalkoxy compounds described below or the two compounds were used in amounts described below instead of tetraethoxy silane in the solution of the alkoxide compound.

| | | |
|---|---|---|
| Conductive member 15: | 3-Glycidoxypropyl trimethoxy | 5.0 parts |
| | silane | |
| Conductive member 16: | Diethyl dimethoxy silane | 5.0 parts |
| Conductive member 17: | Tetramethoxy silane | 5.0 parts |
| Conductive member 18: | Ureidopropyl triethoxy silane | 5.0 parts |
| Conductive member 19: | Tetrapropoxy titanate | 5.0 parts |
| Conductive member 20: | Tetraethoxy zirconate | 5.0 parts |
| Conductive member 21: | 3-Glycidoxypropyl trimethoxy | 2.5 parts |
| | silane | |
| | Tetraethoxy silane | 2.5 parts |
| Conductive member 22: | 3-Glycidoxypropyl trimethoxy | 1.0 part |
| | silane | |
| | Tetraethoxy silane | 4.0 parts |
| Conductive member 23: | 3-Glycidoxypropyl trimethoxy | 4.0 parts |
| | silane | |
| | Tetraethoxy silane | 1.0 part |

### (Production of Conductive Member 24)

A conductive member 24 was obtained in the same manner as in the production of the conductive member 14 except that the PET substrate 101 was changed to the glass substrate produced in Preparation Example 2.

<<Evaluation>>

The surface resistance value, total light transmittance, haze, wearing resistance, heat resistance, resistance to moist heat, and flexibility of each obtained conductive member were evaluated by the same methods as mentioned above. The surface resistance value, the total light transmittance, and the haze were evaluated by the following criteria. The evaluation results are listed in Table 5.

### <Surface Resistance Value>

Rank 5: Very excellent level, at which surface resistance value is less than 100 Ω/sq.
Rank 4: Excellent level, at which surface resistance value is 100 Ω/sq. or more and less than 150 Ω/sq.
Rank 3: Acceptable level, at which surface resistance value is 150 Ω/sq. or more and less than 200 Ω/sq.
Rank 2: Slightly problematic level, at which surface resistance value is 200 Ω/sq. or more and less than 1000 Ω/sq.
Rank 1: Problematic level, at which surface resistance value is 1000 Ω/sq. or more

<Optical Properties (Total Light Transmittance)>
Rank A: Good level, at which transmittance is 90% or more
Rank B: Slightly problematic level, at which transmittance is 85% or more and less than 90%

<Optical Properties (Haze)>
Rank A: Excellent level, at which haze value is less than 1.5%
Rank B: Good level, at which haze value is 1.5% or more and less than 2.0%
Rank C: Slightly problematic level, at which haze value is 2.0% or more and less than 2.5%
Rank D: Problematic level, at which haze value is 2.5 or more

TABLE 4

| | Evaluation results | | | | | | | | |
|---|---|---|---|---|---|---|---|---|---|
| | | | | | Heat | | Resistance to | | |
| | Surface | | | | resistance | | moist heat | | |
| Conductive | resistance | Total light | | Wearing | Change in | Change | Change in | Change | |
| member | value | transmittance | Haze | resistance | resistance | in haze | resistance | in haze | Flexibility |
| 14 | 4 | A | B | 1.11 | 1.37 | 0.21 | 1.22 | 0.20 | 2.02 |
| 15 | 4 | A | B | 4.90 | 1.42 | 0.28 | 1.23 | 0.28 | 1.02 |
| 16 | 4 | A | B | 4.58 | 1.41 | 0.26 | 1.22 | 0.25 | 1.13 |
| 17 | 4 | A | B | 1.12 | 1.35 | 0.22 | 1.19 | 0.21 | 2.13 |
| 18 | 4 | A | B | 4.76 | 1.38 | 0.24 | 1.24 | 0.23 | 1.11 |
| 19 | 4 | A | B | 1.39 | 1.43 | 0.23 | 1.30 | 0.24 | 1.89 |
| 20 | 4 | A | B | 1.46 | 1.38 | 0.25 | 1.28 | 0.26 | 1.96 |
| 21 | 4 | A | B | 1.19 | 1.38 | 0.27 | 1.31 | 0.28 | 1.10 |
| 22 | 4 | A | B | 1.15 | 1.55 | 0.24 | 1.29 | 0.26 | 1.36 |
| 23 | 4 | A | B | 1.59 | 1.43 | 0.31 | 1.33 | 0.26 | 1.08 |
| 24 | 4 | A | B | 1.10 | 1.36 | 0.20 | 1.21 | 0.21 | — |

Based on the results of Table 4, it is found that the conductive members excellent in wearing resistance, heat resistance, resistance to moist heat, and flexibility can be provided even when various alkoxide compounds are used.

(Production of Conductive Members 25 to 32)

Conductive members 25 to 32 were obtained in the same manner as the production of the conductive member 14 except that silver nanowire aqueous dispersions (2) to (9) that have different average major axis lengths and average minor axis lengths and are listed in Table 5 below were used instead of the silver nanowire aqueous dispersion (1).

TABLE 5

| | Aqueous dispersion of Silver nanowire | | |
|---|---|---|---|
| Conductive | | Average major axis length | Average minor axis |
| member | No. | (μm) | length (nm) |
| 25 | (2) | 22.0 | 32.5 |
| 26 | (3) | 25.5 | 45.9 |
| 27 | (4) | 18.5 | 62.7 |
| 28 | (5) | 15.5 | 20.4 |
| 29 | (6) | 8.0 | 18.7 |
| 30 | (7) | 10.8 | 28.9 |
| 31 | (8) | 9.2 | 47.8 |
| 32 | (9) | 8.8 | 61.2 |

(Production of Conductive Member 33)

A surface of the second adhesive layer 32 of the PET substrate 101 produced in Preparation Example 3 was subjected to corona discharge treatment, and 0.1% aqueous solution of N-β(aminoethyl)γ-aminopropyl trimethoxy silane (KBM-603 (mentioned above)) was then coated by a bar coating method, so that the amount of a coated solid was 0.007 g/m², and was dried at 175° C. for 1 minute to form a functional layer 33. Thus, a PET substrate 102 having the configuration shown in FIG. 2, which includes an intermediate layer 30 including a three-layer configuration of an adhesive layer 31, an adhesive layer 32, and the functional layer 33, was produced.

A conductive layer 20 which is the same as the conductive layer of the conductive member 14 was formed on the PET substrate 102 to produce a non-patterned conductive member 33 represented in the cross-sectional view of FIG. 2. The non-patterned conductive member 33 was patterned in the same manner as in the case of the conductive member 14 to obtain a conductive member 33.

(Production of Conductive Members 34 to 41)

Conductive members 34 to 41 were obtained in the same manner as the production of the conductive member 33 except that N-β(aminoethyl)γ-aminopropyl trimethoxy silane (KBM-603 (mentioned above)) was changed to compounds described below in the formation of the functional layer 33 in the PET substrate 102 used in the conductive member 33.

Conductive member 34: Ureidopropyl triethoxy silane

Conductive member 35: 3-Aminopropyl triethoxy silane

Conductive member 36: 3-Mercaptopropyl trimethoxy silane

Conductive member 37: Polyacrylic acid (mass average molecular weight: 50,000)

Conductive member 38: Homopolymer of PHOSMER M (mentioned above) (mass average molecular weight of 20,000)

Conductive member 39: Polyacrylamide (mass average molecular weight of 100,000)

Conductive member 40: Poly(p-sodium styrenesulfonate) (mass average molecular weight of 50,000)

Conductive member 41: Bis(hexamethylene)triamine

<<Evaluation>>

Each obtained conductive member was evaluated in the same manner as in the case of the conductive member 14. The results are listed in Table 6.

TABLE 6

| | Evaluation results | | | | | | | | |
|---|---|---|---|---|---|---|---|---|---|
| | | | | | Heat | | Resistance to | | |
| | Surface | | | | resistance | | moist heat | | |
| Conductive | resistance | Total light | | Wearing | Change in | Change in | Change in | Change in | |
| member | value | transmittance | Haze | resistance | resistance | haze | resistance | haze | Flexibility |
| 25 | 4 | A | B | 1.11 | 1.42 | 0.20 | 1.30 | 0.26 | 2.05 |
| 26 | 4 | B | C | 1.13 | 1.28 | 0.18 | 1.25 | 0.24 | 2.03 |
| 27 | 3 | B | C | 1.28 | 1.17 | 0.13 | 1.23 | 0.18 | 2.16 |
| 28 | 4 | A | B | 1.07 | 1.16 | 0.14 | 1.19 | 0.17 | 2.05 |
| 29 | 4 | A | A | 1.02 | 1.35 | 0.19 | 1.30 | 0.26 | 2.02 |
| 30 | 4 | A | B | 1.05 | 1.32 | 0.18 | 1.26 | 0.24 | 2.05 |
| 31 | 4 | A | C | 1.28 | 1.26 | 0.15 | 1.26 | 0.21 | 2.06 |
| 32 | 3 | A | C | 1.42 | 1.15 | 0.10 | 1.23 | 0.21 | 2.09 |
| 33 | 4 | A | B | 1.05 | 1.18 | 0.10 | 1.24 | 0.14 | 2.04 |
| 34 | 4 | A | B | 1.03 | 1.20 | 0.15 | 1.06 | 0.16 | 2.05 |
| 35 | 4 | A | B | 1.05 | 1.19 | 0.13 | 1.24 | 0.14 | 2.07 |
| 36 | 3 | A | B | 1.03 | 1.15 | 0.11 | 1.11 | 0.08 | 2.02 |
| 37 | 4 | A | B | 1.13 | 1.19 | 0.15 | 1.25 | 0.14 | 2.03 |
| 38 | 3 | A | B | 1.05 | 1.15 | 0.11 | 1.10 | 0.11 | 2.03 |
| 39 | 4 | A | B | 1.08 | 1.52 | 0.19 | 1.25 | 0.15 | 2.04 |
| 40 | 4 | A | B | 1.06 | 1.48 | 0.18 | 1.18 | 0.16 | 2.02 |
| 41 | 4 | A | B | 1.05 | 1.35 | 0.17 | 1.20 | 0.15 | 2.03 |

Based on the results listed in Table 6, the conductive member according to one embodiment of the present invention can be considered to be excellent in electrical conductivity, total light transmittance, haze, and film strength. It is found that the significant effect of enhancing wearing resistance is exhibited by disposing the functional layer including the compound having an amide group, an amino group, a mercapto group, a carboxylic acid group, a sulfonic acid group, a phosphate group, or a phosphonic acid group as the intermediate layer which contacts the conductive layer.

(Production of Conductive Member 42)

A conductive member 42 was obtained in the same manner as in the case of the conductive member 1 except that a silver nanowire aqueous dispersion (10) in which a silver nanowire dispersion described in Example 1 and Example 2 (section 8 in paragraph 0151 to section 9 in paragraph 0160) of U.S. Patent Application Publication No. 2011/0174190 A1 was diluted at 0.85% with distilled water was used instead of the silver nanowire aqueous dispersion (1).

(Production of Conductive Members 43 to 51)

Conductive members 43 to 51 were obtained in the same manner as in the case of the conductive member 7, 8, 9, 10, 15, 17, 33, 34, or 35 respectively except that the silver nanowire aqueous dispersion (1) was changed to the silver nanowire aqueous dispersion (10) as described in the following correspondence.

Conductive member 43: Binder configuration of conductive member 7+silver nanowire aqueous dispersion (10)

Conductive member 44: Binder configuration of conductive member 8+silver nanowire aqueous dispersion (10)

Conductive member 45: Binder configuration of conductive member 9+silver nanowire aqueous dispersion (10)

Conductive member 46: Binder configuration of conductive member 10+silver nanowire aqueous dispersion (10)

Conductive member 47: Binder configuration of conductive member 15+silver nanowire aqueous dispersion (10)

Conductive member 48: Binder configuration of conductive member 17+silver nanowire aqueous dispersion (10)

Conductive member 49: Binder configuration of conductive member 33+silver nanowire aqueous dispersion (10)

Conductive member 50: Binder configuration of conductive member 34+silver nanowire aqueous dispersion (10)

Conductive member 51: Binder configuration of conductive member 35+silver nanowire aqueous dispersion (10)

<<Evaluation>>

The surface resistivity, optical properties (total light transmittance and haze), film strength, wearing resistance, heat resistance, resistance to moist heat, and flexibility of each obtained conductive member were evaluated by the same method as mentioned above. The results are listed in Table 7.

TABLE 7

| | Evaluation results | | | | | | | | |
|---|---|---|---|---|---|---|---|---|---|
| | | | | | Heat | | Resistance to | | |
| | Surface | | | | resistance | | moist heat | | |
| Conductive | resistance | Total light | | Wearing | Change in | Change | Change in | Change | |
| member | value | transmittance | Haze | resistance | resistance | in haze | resistance | in haze | Flexibility |
| 42 | 5 | A | A | 1.12 | 1.37 | 0.21 | 1.20 | 0.22 | 2.08 |
| 43 | 4 | A | A | 6.32 | 1.12 | 0.29 | 1.83 | 0.24 | 2.10 |
| 44 | 4 | A | A | 1.11 | 1.25 | 0.26 | 1.47 | 0.17 | 2.09 |
| 45 | 4 | A | A | 1.06 | 1.16 | 0.21 | 1.21 | 0.15 | 2.13 |
| 46 | 4 | A | A | 1.05 | 1.12 | 0.18 | 1.17 | 0.13 | 2.17 |
| 47 | 4 | A | B | 4.99 | 1.40 | 0.26 | 1.21 | 0.27 | 1.03 |
| 48 | 4 | A | B | 1.13 | 1.36 | 0.20 | 1.18 | 0.22 | 2.16 |
| 49 | 4 | A | B | 1.04 | 1.17 | 0.11 | 1.23 | 0.15 | 2.05 |
| 50 | 4 | A | B | 1.02 | 1.21 | 0.16 | 1.08 | 0.15 | 2.06 |
| 51 | 4 | A | B | 1.05 | 1.18 | 0.12 | 1.23 | 0.17 | 2.05 |

As is clear in Table 7, based on the evaluation results of the conductive members 42 to 51, it is found that the conductive member according to one embodiment of the present invention has excellent total light transmittance, haze, film strength and wearing resistance even if the silver nanowires described in U.S. Patent Application Publication No. 2011/0174190 A1 are used.

<Production of Integrated Solar Cell>

### —Production of Amorphous Solar Cell (Super-Straight Type)—

In the same manner as in the case of the conductive member 14, a conductive layer was formed on a glass substrate to form a transparent conductive film, except that patterning treatment was omitted so that a transparent conductive film of which the whole surface was homogeneous was made. On the upper section thereof, p-type amorphous silicon with a film thickness of about 15 nm, i-type amorphous silicon with a film thickness of about 350 nm, and n-type amorphous silicon with a film thickness of about 30 nm were formed by a plasma CVD method. Further, a gallium-added zinc oxide layer with a thickness of 20 nm and a silver layer with a thickness of 200 nm were formed as a back surface reflective electrode. A photoelectric conversion element 101 (integrated solar cell) was thus produced.

—Production of CIGS Solar Cell (Sub-Straight Type)—

On a soda-lime glass substrate, a molybdenum electrode with a film thickness of around 500 nm was formed by a direct current magnetron sputtering method, Cu(In0.6Ga0.4)Se2 thin film as a chalcopyrite semiconductor material with a film thickness of about 2.5 μm was formed thereon by a vacuum deposition method, and a cadmium sulfide thin film with a film thickness of about 50 nm was further formed thereon by a solution deposition method.

The same conductive layer as the conductive layer of the conductive member 14 was formed thereon, and a transparent conductive film was formed on the glass substrate. A photoelectric conversion element 201 (CIGS solar cell) was thus produced.

The conversion efficiency of each produced solar cell was evaluated as described below.

<Evaluation of Solar Cell Characteristics (Conversion Efficiency)>

The efficiency of each solar cell was measured by irradiation with pseudo-sunlight at an air mass (AM) of 1.5 and an irradiation intensity of 100 mW/cm². As a result, any element exhibited a conversion efficiency of 9%.

Based on the results, it was found that high conversion efficiency was obtained in any integrated solar cell system by using a laminate for forming a conductive film according to one embodiment of the present invention for forming a transparent conductive film.

—Production of Touch Panel—

A transparent conductive film was formed on a glass substrate in the same manner as the formation of the conductive layer of the conductive member 14. A touch panel was produced using the resultant transparent conductive film by a method described in “Current Touch Panel Technology” (published on Jul. 6, 2009, Techno Times Co., Ltd.), “Technology and Development of Touch Panel” supervised by Yuji Mitani, CMC Publishing Co., Ltd. (published in December, 2004), “FPD International 2009 Forum T-11 Lecture Textbook”, “Cypress Semiconductor Corporation Application Note AN2292”, and the like.

It was found that, in the case of using the produced touch panel, the touch panel excellent in visibility due to improvement in light transmittance and excellent in response to the input of characters and the like or the operation of an image plane by at least one of bare hands, gloved hands, and tools for instruction due to improvement in electrical conductivity can be produced.

### INDUSTRIAL APPLICABILITY

The laminate for forming a conductive film according to one embodiment of the present invention can be preferably used for producing, e.g., a pattern-shaped transparent conductive film, a touch panel, an antistatic material for a display, an electromagnetic wave shield, an electrode for an organic EL display, an electrode for an inorganic EL display, electronic paper, an electrode for a flexible display, an antistatic film for a flexible display, a display element, or an integrated solar cell, since the laminate has excellent patterning properties in development and is excellent in transparency, electrical conductivity and durability (film strength) even if the laminate is used without being processed or used as a transfer material.

The disclosures of Japanese Patent Application No. 2011-102135, Japanese Patent Application No. 2012-019250, and Japanese Patent Application No. 2012-068239 are incorporated herein by reference in their entirety.

All the literature, patents, patent applications, and technical standards described herein are incorporated herein by reference to the same extent as if each individual literature, patent, patent application, or technical standard was specifically and individually indicated as being incorporated by reference.

What is claimed is:

1. A conductive member comprising a base material and a conductive layer disposed on the base material, wherein:
the conductive layer comprises:
a metal nanowire that comprises a metal element (a) and has an average minor axis length of 150 nm or less; and
a sol-gel cured product obtained by hydrolyzing and polycondensing an alkoxide compound of an element (b) selected from the group consisting of Si, Ti, Zr, and Al; and
a ratio of a substance amount of the element (b) contained in the conductive layer to a substance amount of the metal element (a) contained in the conductive layer is in a range of from 0.10/1 to 22/1.

2. The conductive member according to claim 1, wherein
the sol-gel cured product comprises a three-dimensional crosslinked structure comprising at least one selected from the group consisting of a partial structure represented by the following Formula (1), a partial structure represented by the following Formula (2), and a partial structure represented by Formula (3): 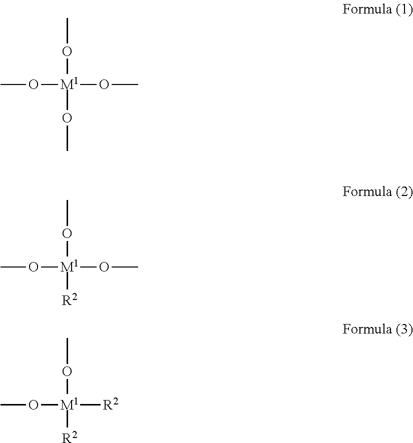
wherein M¹ represents an element selected from the group consisting of Si, Ti, and Zr; and each R² independently represents a hydrogen atom or a hydrocarbon group.

3. A conductive member, comprising a base material and a conductive layer disposed on the base material, wherein:
the conductive layer comprises:
a metal nanowire that comprises a metal element (a) and has an average minor axis length of 150 nm or less; and
a sol-gel cured product obtained by hydrolyzing and polycondensing an alkoxide compound of an element (b) selected from the group consisting of Si, Ti, Zr, and Al; and
a ratio of the mass of the alkoxide compound hydrolyzed and polycondensed to form the sol-gel cured product in the conductive layer to the mass of the metal nanowire contained in the conductive layer is in a range of from 0.25/1 to 30/1.

4. The conductive member according to claim 3, wherein
the sol-gel cured product comprises a three-dimensional crosslinked structure comprising at least one selected from the group consisting of a partial structure represented by the following Formula (1), a partial structure represented by the following Formula (2), and a partial structure represented by Formula (3): 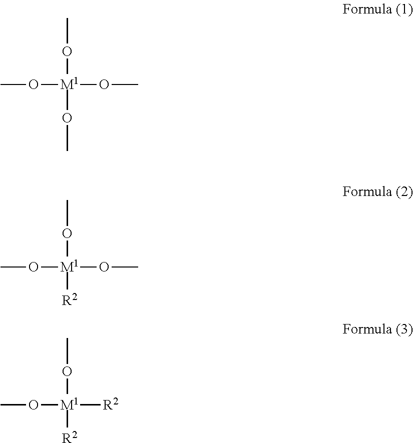
wherein M¹ represents an element selected from the group consisting of Si, Ti, and Zr; and each R² independently represents a hydrogen atom or a hydrocarbon group.

5. The conductive member according to claim 1, wherein the alkoxide compound comprises a compound represented by the following Formula (I):
M¹(OR¹)ₐR²₄₋ₐ (I)
wherein M¹ represents an element selected from the group consisting of Si, Ti, and Zr; R¹ and each R² independently represent a hydrogen atom or a hydrocarbon group; and a represents an integer from 2 to 4.

6. The conductive member according to claim 3, wherein the alkoxide compound comprises a compound represented by the following Formula (I):
M¹(OR¹)ₐR²₄₋ₐ (I)
wherein M¹ represents an element selected from the group consisting of Si, Ti, and Zr; R¹ and each R² independently represent a hydrogen atom or a hydrocarbon group; and a represents an integer from 2 to 4.

7. The conductive member according to claim 2, wherein M¹ is Si.

8. The conductive member according to claim 4, wherein M¹ is Si.

9. The conductive member according to claim 5, wherein M¹ is Si.

10. The conductive member according to claim 6, wherein M¹ is Si.

11. The conductive member according to claim 1, wherein the metal nanowire is a silver nanowire.

12. The conductive member according to claim 1, wherein a surface resistivity of the conductive layer measured from a surface thereof is no more than 1,000 Ω/sq.

13. The conductive member according to claim 1, wherein the conductive layer has an average film thickness of 0.005 μm to 0.5 μm.

14. The conductive member according to claim 1, further comprising an intermediate layer which is disposed between the base material and the conductive layer and which comprises a compound containing a functional group capable of interacting with the metal nanowire.

15. The conductive member according to claim 14, wherein the functional group is selected from the group consisting of an amide group, an amino group, a mercapto group, a carboxylic acid group, a sulfonic acid group, a phosphate group, a phosphonic acid group, and salts of these groups.

16. The conductive member according to claim 1, wherein, in a case in which an wearing resistance test is conducted in which gauze is pressed on a surface of the conductive layer at a pressure of 125 g/cm² to rub the surface to and fro with the gauze 50 times using a continuous loading scratching tester, a ratio of a surface resistivity (Ω/sq.) of the conductive layer after the wearing resistance test to a surface resistivity (Ω/sq.) of the conductive layer before the wearing resistance test is 100 or less.

17. The conductive member according to claim 1, wherein
a ratio of a surface resistivity (Ω/sq.) of the conductive layer after being subjected to a bending test to a surface resistivity (Ω/sq.) of the conductive layer of the conductive member before subjected to the bending test is 5.0 or less, and
the bending test comprises subjecting the conductive member to a 20-time bending test using a cylindrical mandrel bending tester equipped with a cylindrical mandrel having a diameter of 10 mm.

18. A method of producing the conductive member according to claim 3, comprising:
(a) coating the base material with a liquid composition comprising the metal nanowire and the alkoxide compound in which a ratio of the mass of the alkoxide compound to the mass of the metal nanowire is in a range of from 0.25/1 to 30/1, to form a liquid film of the liquid composition on the base material; and
(b) hydrolyzing and polycondensing the alkoxide compound in the liquid film to obtain the sol-gel cured product.

19. The method of producing the conductive member according to claim 18, further comprising forming at least one intermediate layer on a surface of the base material on which the liquid film is formed, prior to the (a).

20. The method of producing the conductive member according to claim 19, further comprising (c) forming a pattern-shaped non-conductive region on the conductive layer after the (b) so that the conductive layer comprises a non-conductive region and a conductive region.

21. A touch panel, comprising the conductive member according to claim 1.

22. A solar cell, comprising the conductive member according to claim 1.

23. A metal nanowire-containing composition comprising: a metal nanowire having an average minor axis length of 150 nm or less; and at least one alkoxide compound of an element (b) selected from the group consisting of Si, Ti, Zr, and Al, wherein a ratio of the mass of the alkoxide compound to the mass of the metal nanowire is in a range of from 0.25/1 to 30/1.
